(19) United States
(12) Patent Application Publication
(10) Pub. No.: US 2007/0075374 A1
(43) Pub. Date: Apr. 5, 2007

(54) Semicondutor device and method for fabricating the same

(76) Inventor: Chiaki Kudou, Hyogo (JP)

Correspondence Address: MCDERMOTT WILL & EMERY LLP, 600 13TH STREET, N.W., WASHINGTON, DC, 20005-3096, US

(21) Appl. No.: 11/475,179

(22) Filed: Jun. 27, 2006

(30) Foreign Application Priority Data
Oct. 5, 2005 (JP) 2005-292005

(51) Int. Cl. H01L 29/76

(52) U.S. Cl. 257/365

(57) ABSTRACT

A semiconductor device includes: a first field-effect transistor including a first gate electrode; and a second field-effect transistor including a second gate electrode. The first and second gate electrodes are fully silicided with metal and have different gate lengths. A trench is formed in an upper portion of the first gate electrode such that a rim portion of the first gate electrode is high and a middle portion of the first gate electrode in a gate length direction is low. The trench has a width depending on the gate length of the first gate electrode.

### CROSS-REFERENCE TO RELATED APPLICATION

This application claims priority under 35 U.S.C. §119 on Patent Application No. 2005-292005 filed in Japan on Oct. 5, 2005, the entire contents of which are hereby incorporated by reference.

### BACKGROUND OF THE INVENTION

The present invention relates to semiconductor devices and methods for fabricating the devices, and particularly relates to semiconductor devices including field-effect transistors with fully-silicided (FUSI) structures and methods for fabricating the devices.

The integration degree of semiconductor elements integrated in a semiconductor integrated circuit device has increased to date. For example, a technique for miniaturizing a gate electrode of a metal-insulator-semiconductor (MIS) field-effect transistor (FET) and reducing the electrical thickness of a gate insulating film by using a material with a high dielectric constant as the insulating material is being used. However, it is generally impossible to prevent depletion from occurring in polysilicon used for the gate electrode even by impurity implantation, resulting in that this depletion increases the electrical thickness of the gate insulating film. This hinders enhancement of performance of an FET.

In recent years, gate electrode structures in which depletion in gate electrodes is prevented have been proposed. Specifically, a fully-silicided (FUSI) structure obtained by causing reaction between a silicon material forming a gate electrode and a metal material and thereby changing the entire silicon material into silicide is reported as an effective technique for suppressing depletion in the gate electrode.

For example, in Literature 1 (2004 IEEE, Proposal of New HfSiON CMOS Fabrication Process (HAMDAMA) for Low Standby Power Device, T. Aoyama et. al), a method for forming a FUSI structure is proposed. In Literature 2 (2004 IEEE, Dual Workfunction Ni-Silicide/HfSiON Gate Stacks by Phase-Controlled Full-Silicidation (PC-FUSI) Technique for 45 nm-node LSTP and LOP Devices, K. Takahashi et. al), different materials are used for FUSI electrodes in an n-FET and a p-FET, e.g., NiSi is used for the n-FET and Ni₃Si is used for the p-FET, is proposed.

FIGS. 18A through 18D illustrate cross-sectional structures of a main portion in processes of a method for fabricating a conventional MISFET disclosed in Literature 1.

First, as illustrated in FIG. 18A, an isolation film 2 is formed in an upper portion of a semiconductor substrate 1 made of silicon. Thereafter, a gate insulating film 3 and a conductive polysilicon film are formed in this order on an n-FET region A and a p-FET region B of the semiconductor substrate 1 defined by the isolation film 2. Subsequently, the polysilicon film is patterned, thereby forming a first gate-electrode formation film 4A and a second gate-electrode formation film 4B in the n-FET region A and the p-FET region B, respectively. Then, insulating sidewall spacers 5 are formed on side faces of the gate-electrode formation films 4A and 4B. Subsequently, using the sidewall spacers 5 as masks, source/drain regions 6 are formed in an active region of the semiconductor substrate 1. Thereafter, an interlayer insulating film 7 is formed over the semiconductor substrate 1 to cover the gate-electrode formation films 4A and 4B and the sidewall spacers 5. Then, chemical mechanical polishing (CMP), for example, is performed on the interlayer insulating film 7, thereby exposing the gate-electrode formation films 4A and 4B.

Next, as illustrated in FIG. 18B, a resist pattern 8 for exposing the p-FET region B is formed on the interlayer insulating film 7. Then, using the resist pattern 8 as a mask, an upper portion of the second gate-electrode formation film 4B exposed from the interlayer insulating film 7 in the p-FET region B is removed by etching.

Thereafter, as illustrated in FIG. 18C, the resist pattern 8 is removed, and then a metal film 9 made of nickel is deposited over the interlayer insulating film 7 from which the gate-electrode formation films 4A and 4B are exposed.

Then, as illustrated in FIG. 18D, heat treatment is performed on the semiconductor substrate 1 to cause the gate-electrode formation films 4A and 4B of polysilicon and the metal film 9 to react with each other, thereby forming a first gate electrode 10A having its upper portion silicided in the n-FET region A and a fully-silicided second gate electrode 10B in the p-FET region B. In Literature 1, a lower portion of the first gate electrode 10A forming the n-FET is still polysilicon and a lower portion of the second gate electrode 10B forming the p-FET is NiSi.

In Literature 2, a thick metal film is deposited so that the entire first gate electrode 10A is made of NiSi and the entire second gate electrode 10B is made of Ni₃Si.

The present inventor conducted various studies on FUSI structures, to find that full silicidation nonuniformly proceeds in a polysilicon film for forming a gate electrode of a MISFET during full silicidation of the gate electrode. This phenomenon is pronounced especially when the gate length is relatively large. FIGS. 19A and 19B illustrate this phenomenon.

As illustrated in FIG. 19A, a first gate-electrode formation film 4C made of polysilicon and a second gate-electrode formation film 4D made of polysilicon and having a gate length larger than that of the first gate-electrode formation film 4C are formed on the active region of the semiconductor substrate 1. In this case, in a conventional process of siliciding a gate electrode, metal atoms are diffused in polysilicon not only from portions of the metal film 9 on the gate-electrode formation films 4C and 4D but also from portions of the metal film 9 on the upper ends of the sidewall spacers 5 and their neighboring portions. Specifically, metal is excessively supplied from portions of the metal film 9 deposited over the gate-electrode formation films 4C and 4D to both sides in the gate length direction, resulting in that excessive silicidation occurs near the sidewall spacers 5 in polysilicon.

In this manner, as illustrated in FIG. 19B, a FUSI first gate electrode 10C is formed out of the first gate-electrode formation film 4C having a relatively small gate length. On the other hand, with respect to the second gate-electrode formation film 4D having a relatively large gate length, metal is supplied only from portions on top of the polysilicon sidewall spacers 5 to a portion of the second gate-electrode formation film 4D apart from the sidewall spacers 5, resulting in that a second gate electrode 10D having a nonuniform composition is formed out of the second gate-electrode formation film 4D. In this manner, in a FET having a relatively large gate length, the composition of the gate electrode differs between a portion near the sidewall spacers 5 and a middle portion of the gate electrode. This causes the threshold voltage of the FET to vary.

In the case of applying the conventional full silicidation method to a resistor or an upper electrode of a capacitor, the resistance value varies in the resistor or the capacitance value varies in the capacitor.

### SUMMARY OF THE INVENTION

It is therefore an object of the present invention to enable a plurality of gate electrodes having different gate lengths to have a FUSI structure having a uniform composition irrespective of the gate lengths.

To achieve the object, in a semiconductor device and a method for fabricating the device according to the present invention, upper portions of a gate-electrode formation film of silicon provided with sidewall spacers are removed so that the upper face of the gate-electrode formation film is lower than the upper faces of the sidewall spacers and separate meal films for silicidation are formed on gate electrodes whose upper faces are lowered. Each of the resultant gate electrodes has a recess shape in its upper portion such that the rim of the gate electrode is high and the middle thereof in the gate length direction is low.

Specifically, a semiconductor device according to the present invention includes: a first field-effect transistor including a first gate electrode; and a second field-effect transistor including a second gate electrode, and each of the first gate electrode and the second gate electrode is fully silicided with a metal, the first gate electrode and the second gate electrode have different gate lengths, a trench is formed in an upper portion of the first gate electrode such that a rim portion of the first gate electrode is high and a middle portion of the first gate electrode in a gate length direction is low, and the trench has a width depending on a gate length of the first gate electrode.

In the semiconductor device, it is preferable that a trench is formed in an upper portion of the second gate electrode such that a rim portion of the second gate electrode is high and a middle portion of the second gate electrode in a gate length direction is low.

In the semiconductor device, the first gate electrode preferably has a gate length larger than that of the second gate electrode.

In the semiconductor device, the first gate electrode and the second gate electrode preferably have an identical metal content.

In the semiconductor device, the first field-effect transistor and the second field-effect transistor are preferably n-type field-effect transistors.

In the semiconductor device, the first field-effect transistor and the second field-effect transistor are preferably p-type field-effect transistors.

Preferably, the semiconductor device further includes: a third field-effect transistor including a third gate electrode; and a fourth field-effect transistor including a fourth gate electrode, the third field-effect transistor and the fourth field-effect transistor are n-type field-effect transistors, each of the third gate electrode and the fourth gate electrode is fully silicided with a metal, the third gate electrode and the fourth gate electrode have different gate lengths, and convex shapes are formed in upper portions of the respective third and fourth gate electrodes such that middle portions of the third and fourth gate electrodes in respective gate length directions are high.

Preferably, the semiconductor device further includes: a third field-effect transistor including a third gate electrode; and a fourth field-effect transistor including a fourth gate electrode, the third field-effect transistor and the fourth field-effect transistor are n-type field-effect transistors, each of the third gate electrode and the fourth gate electrode is fully silicided with a metal, the third gate electrode and the fourth gate electrode have different gate lengths, and trenches are formed in upper portions of the respective third and fourth gate electrodes such that rim portions of the third and fourth gate electrodes are high and middle portions of the third and fourth gate electrodes in respective gate length directions are low.

In this case, the third gate electrode and the fourth gate electrode preferably have an identical metal content.

In this case, each of the first gate electrode and the second gate electrode preferably has a metal content higher than that of each of the third gate electrode and the fourth gate electrode.

The semiconductor device preferably further includes a resistor fully silicided with the metal, a trench being formed in an upper portion of the resistor such that a rim portion of the resistor is high and a middle portion of the resistor in a width direction is low.

The semiconductor device preferably further includes a capacitor including an upper electrode fully silicided with the metal, and a trench is formed in the upper electrode such that a rim portion of the upper electrode is high and a middle portion of the upper electrode in a width direction is low.

A method for fabricating a semiconductor device according to the present invention is a method for fabricating a semiconductor device including a first field-effect transistor including a first gate electrode and a second field-effect transistor including a second gate electrode. The method includes the steps of: (a) forming first and second silicon gate electrodes made of silicon and having different gate lengths on a semiconductor region; (b) forming insulating sidewall spacers on side faces of the first silicon gate electrode and the second silicon gate electrode; (c) forming a height difference such that exposed upper surfaces of the first and second silicon gate electrodes are lower than upper ends of the sidewall spacers; (d) forming a metal film on at least the sidewall spacers, the first silicon gate electrode and the second silicon gate electrode, after the step (c); (e) selectively removing portions of the metal film on the upper ends of the sidewall spacers; and (f) performing heat treatment on the metal film after the step (e), thereby forming a first gate electrode and a second gate electrode fully silicided with the metal film out of the first silicon gate electrode and the second silicon gate electrode.

With the method of the present invention, in the step (e), portions of the metal film on the upper ends of the sidewall spacers are removed, so that the resultant metal films are isolated from each other over the gate electrodes. Accordingly, metal is supplied only from portions on the gate electrodes and is not supplied from the other portions. As a result, the gate electrodes have a uniform composition, irrespective of the sizes (gate lengths) thereof.

In the method, it is preferable that in the step (f), trenches are formed in upper portions of the respective first and second gate electrodes such that rim portions of the first and second gate electrodes are high and middle portions of the first and second gate electrodes in respective gate length directions are low.

In the method, it is preferable that the step (a) includes the step of forming a first protective insulating film and a second protective insulating film on upper surfaces of the first silicon gate electrode and the second silicon gate electrode, the sidewall spacers are also formed on side faces of the first protective insulating film and the second protective insulating film in the step (b), and the first protective insulating film and the second protective insulating film are removed in the step (c), thereby forming the height difference.

In the method, the step (c) preferably includes the step of removing the first protective insulating film and the second protective insulating film, and then etching upper portions of the first silicon gate electrode and the second silicon gate electrode.

In the method, the step (e) preferably includes the steps of: (e1) forming a protective film on the metal film and etching back the protective film, thereby exposing portions of the metal film on upper ends of the sidewall spacers from the protective film; and (e2) etching the metal film using the protective film as a mask, thereby removing portions of the metal film on the upper ends of the sidewall spacers.

Preferably, the method further includes the step (g) of selectively forming an isolation region in an upper portion of the semiconductor region, before the step (a), the step (a) includes the step of forming a silicon resistor element made of silicon on the isolation region, the step (b) includes the step of forming the sidewall spacers on side faces of the silicon resistor element, the step (c) includes the step of forming a height difference such that an exposed upper surface of the silicon resistor element is lower than upper ends of the sidewall spacers, the step (d) includes the step of forming the metal film on the silicon resistor element, the step (e) includes the step of removing portions of the metal film on the upper ends of the sidewall spacers on the silicon resistor element, and the step (f) includes the step of forming a resistor element of a resistor fully silicided with the metal film out of the silicon resistor element.

Then, even in a FUSI resistor, the composition of the FUSI structure is uniform, thus preventing a variation of the resistance value.

Preferably, in the method, the step (a) includes the step of forming, on the semiconductor region, a silicon upper electrode made of silicon, the step (b) includes the step of forming the sidewall spacers on side faces of the silicon upper electrode, the step (c) includes the step of forming a height difference such that an exposed surface of the silicon upper electrode is lower than upper ends of the sidewall spacers, the step (d) includes the step of forming the metal film on the silicon upper electrode, the step (e) includes the step of removing portions of the metal film on the upper ends of the sidewall spacers on the silicon upper electrode, and the step (f) includes the step of forming an upper electrode of a capacitor fully silicided with the metal film out of the silicon upper electrode.

The, even in a capacitor having a FUSI upper electrode, the composition of the FUSI structure is uniform, thus preventing a variation of the capacitance value.

### BRIEF DESCRIPTION OF THE DRAWINGS

FIG. 1 is a cross-sectional view schematically illustrating a semiconductor device according to a first embodiment of the present invention.

FIGS. 2A and 2B schematically illustrate a gate electrode in the semiconductor device of the first embodiment. FIG. 2A is a plan view and FIG. 2B is a cross-sectional view taken along the line IIb-IIb in FIG. 2A.

FIGS. 3A and 3B are cross-sectional views showing respective process steps of a method for fabricating a semiconductor device according to the first embodiment.

FIGS. 4A and 4B are cross-sectional views showing respective process steps of the method for fabricating a semiconductor device according to the first embodiment.

FIGS. 5A and 5B are cross-sectional views showing respective process steps of the method for fabricating a semiconductor device according to the first embodiment.

FIGS. 6A and 6B are cross-sectional views showing respective process steps of the method for fabricating a semiconductor device according to the first embodiment.

FIGS. 7A and 7B are cross-sectional views showing respective process steps of the method for fabricating a semiconductor device according to the first embodiment.

FIGS. 8A through 8C are cross-sectional views schematically illustrating a semiconductor device according to a second embodiment of the present invention.

FIGS. 9A through 9C are cross-sectional views showing respective process steps of a method for fabricating a semiconductor device according to the second embodiment.

FIGS. 10A through 10C are cross-sectional views showing respective process steps of the method for fabricating a semiconductor device according to the second embodiment.

FIGS. 11A through 11C are cross-sectional views showing respective process steps of the method for fabricating a semiconductor device according to the second embodiment.

FIGS. 12A through 12C are cross-sectional views showing respective process steps of the method for fabricating a semiconductor device according to the second embodiment.

FIGS. 13A through 13C are cross-sectional views showing respective process steps of the method for fabricating a semiconductor device according to the second embodiment.

FIGS. 14A through 14C are cross-sectional views showing respective process steps of the method for fabricating a semiconductor device according to the second embodiment.

FIGS. 15A through 15C are cross-sectional views showing respective process steps of the method for fabricating a semiconductor device according to the second embodiment.

FIGS. 16A through 16C are cross-sectional views showing respective process steps of the method for fabricating a semiconductor device according to the second embodiment.

FIGS. 17A through 17C are cross-sectional views schematically illustrating a semiconductor device according to a modified example of the second embodiment.

FIGS. 18A through 18D are cross-sectional views showing respective process steps of a method for fabricating a FET having a conventional FUSI electrode structure.

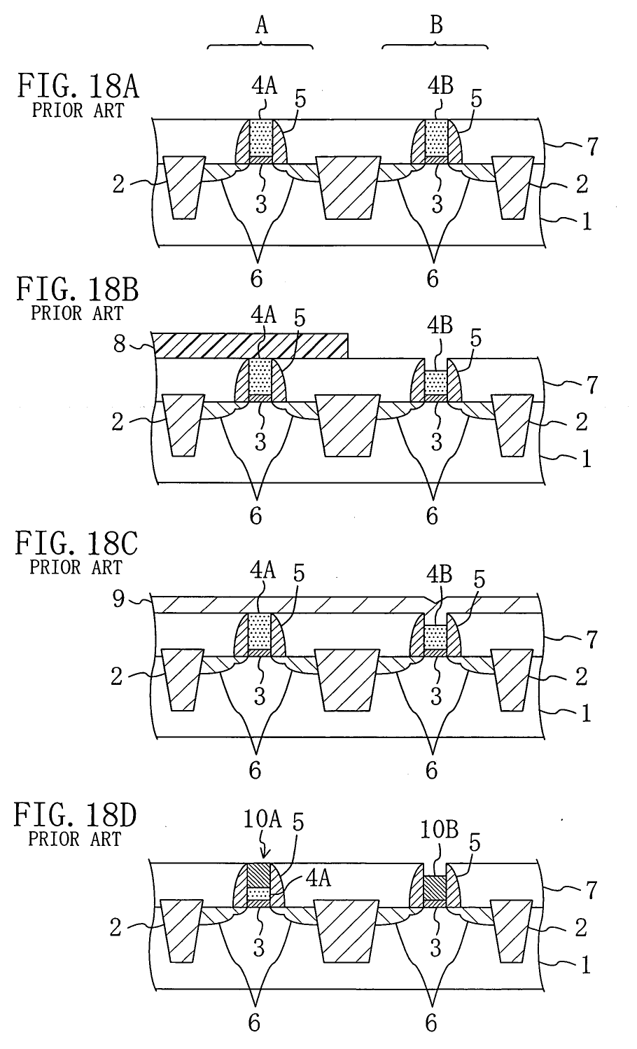

FIGS. 19A and 19B are cross-sectional views showing problems in a method for fabricating a FET having a conventional FUSI electrode structure.

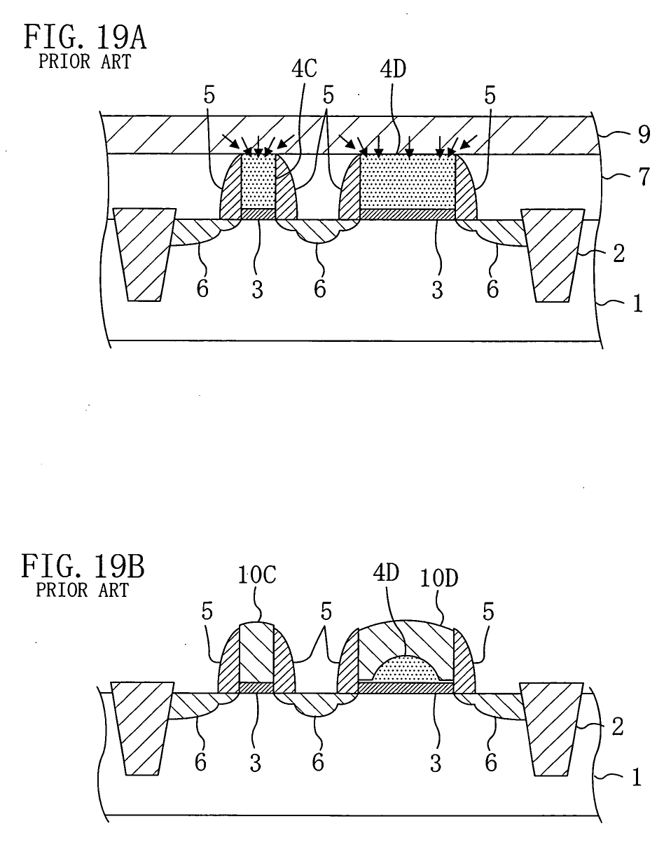

### DETAILED DESCRIPTION OF THE INVENTION

Embodiment 1

A first embodiment of the present invention will be described with reference to the drawings.

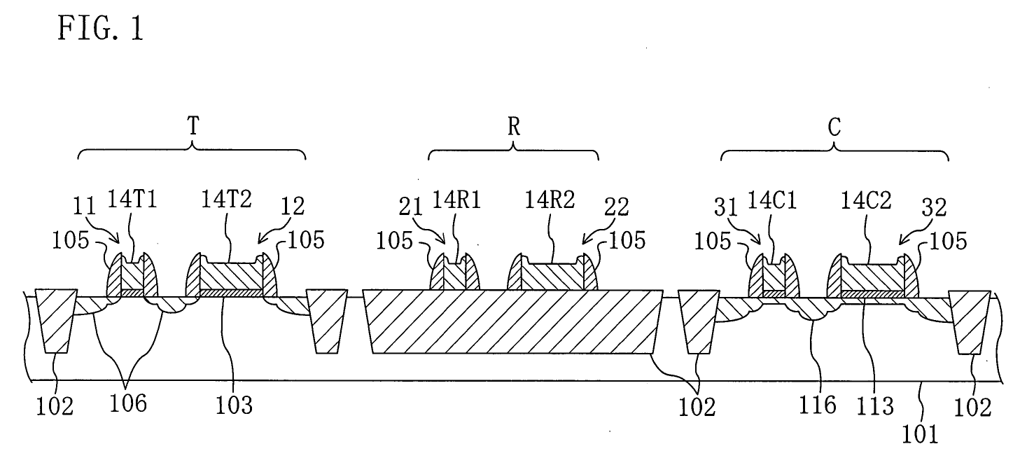

FIG. 1 illustrates a cross-sectional structure of a semiconductor device according to the first embodiment. As illustrated in FIG. 1, an FET region T, a resistor region R and a capacitor region C are defined by an isolation region 102 of shallow trench isolation (STI) in the principal surface of a semiconductor substrate 101 made of, for example, silicon (Si). The resistor region R is provided on the isolation region 102.

In the FET region T, a first n-FET 11 and a second n-FET 12 having different gate lengths are formed. In the resistor region R, a first resistor 21 and a second resistor 22 having different widths are formed. In the capacitor region C, first and second capacitors 31 and 32 whose electrodes (upper electrodes) have different widths are formed.

Each of the first n-FET 11 and the second n-FET 12 in the FET region T includes: a gate insulating film 103 formed on the semiconductor substrate 101; a first gate electrode 14T1 formed on the gate insulating film 103 and made of fully-silicided (FUSI) metal silicide or a second gate electrode 14T2 formed on the gate insulating film 103, made of fully-silicided (FUSI) metal silicide and having a gate length larger than that of the first gate electrode 14T1; sidewall spacers 105 formed on both sides of the gate electrode 14T1 or 14T2 and made of silicon nitride (Si₃N₄); and n-type source/drain regions 106 formed below the gate electrode 14T1 or 14T2 in the semiconductor substrate 101 and doped with n-type impurity ions.

Each of the first resistor 21 and the second resistor 22 in the resistor region R includes: a first resistor element 14R1 made of FUSI metal silicide or a second resistor element 14R2 made of FUSI metal silicide and having a width larger than that of the first resistor element 14R1; and sidewall spacers 105 formed on both sides of the resistor element 14R1 or 14R2.

Each of the first capacitor 31 and the second capacitor 32 in the capacitor region C includes: a capacitive insulating film 113 serving as a MIS capacitor and formed on the semiconductor substrate 101; a first upper electrode 14C1 formed on the capacitive insulating film 113 and made of FUSI metal silicide or a second upper electrode 14C2 formed on the capacitive insulating film 113 and having a width larger than that of the first upper electrode 14C1; sidewall spacers 105 formed on both sides of the upper electrode 14C1 or 14C2; and a lower electrode 116 below the sides of the upper electrode 14C1 or 14C2 and under the capacitive insulating film 113 in the semiconductor substrate 101 and doped with n-type impurity ions.

The first embodiment is characterized in that each of the FUSI gate electrodes 14T1 and 14T2 has a recess shape which is high in both ends in the gate direction and is low in the middle. Likewise, each of the FUSI resistor elements 14R1 and 14R2 and the upper electrodes 14C1 and 14C2 has a recess shape which is high in both ends in the width direction and is low in the middle.

In FIG. 1, the two FETs 11 and 12, the two resistors 21 and 22 and the two capacitors 31 and 32 are shown for convenience. However, a larger number of these components are actually formed on the semiconductor substrate 101. The first n-FET 11 and the second n-FET 12 are formed in the same region defined by the isolation region 102 but may be formed in different regions defined by the isolation region 102. Likewise, the first capacitor 31 and the second capacitor 32 are formed in the same region defined by the isolation region 102 but may be formed in different regions defined by the isolation region 102.

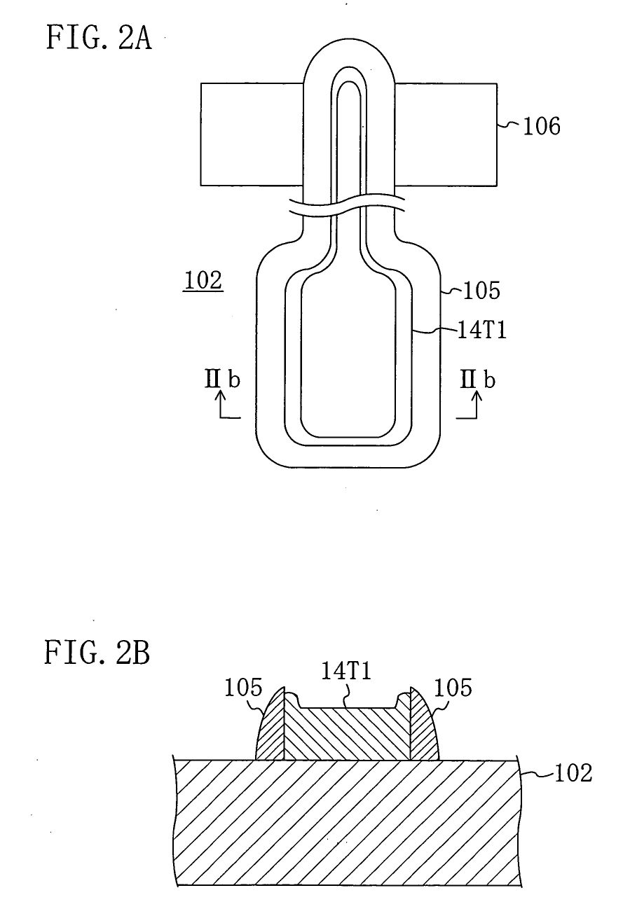

FIG. 2A illustrates a planar structure of the FUSI first gate electrode 14T1 of the semiconductor device of the first embodiment. FIG. 2B illustrates a cross-sectional structure taken along the line IIb-IIb in FIG. 2A. In FIGS. 2A and 2B, components also shown in FIG. 1 are denoted by the same reference numerals. A wide portion of the first gate electrode 14T1 shown in FIG. 2A is a contact portion formed on the isolation region 102. As illustrated in FIGS. 2A and 2B, a sidewall spacer 105 is formed around the first gate electrode 14T1. The rim portion of the first gate electrode 14T1 in contact with the sidewall spacer 105 is higher than a middle portion of the first gate electrode 14T1. In this embodiment, description is given on the first gate electrode 14T1 of the n-FET as an example. However, the first and second resistor elements 14R1 and 14R2 of the resistors 21 and 22 and the first and second upper electrodes 14C1 and 14C2 of the capacitors 31 and 32 as well as the second gate electrode 14T2 have similar structures.

As described above, in the semiconductor device of the first embodiment, the FUSI gate electrodes 14T1 and 14T2, the FUSI resistor elements 14R1 and 14R2 and the FUSI upper electrodes 14C1 and 14C2 whose upper portions have the same structure have the same composition in a self-aligned manner, irrespective of the sizes (planar dimensions) of the gate electrodes 14T1 and 14T2, the resistor elements 14R1 and 14R2 and the upper electrodes 14C1 and 14C2, respectively. Accordingly, in the n-FETs 11 and 12, for example, variation of the threshold voltage due to nonuniformity of the composition depending on the sizes of the first and second gate electrodes 14T1 and 14T2 is prevented. In addition, variation of the resistance value is also prevented in the resistors 21 and 22, and variation of the capacitance value is also prevented in the capacitors. As a result, performance of the semiconductor device is enhanced and integration degree is increased.

In FIG. 1, the first n-FET 11 and the second n-FET 12 are formed in the same region of the semiconductor substrate 101 defined by the isolation region 102, the first capacitor 31 and the second capacitor 32 are formed in the same region of the semiconductor substrate 101 defined by the isolation region 102, for example. These components may be individually formed in respective regions defined by the isolation region 102. Alternatively, two types of the components may be formed in the same region in combination. In this embodiment, the first resistor 21 and the second resistor 22 are formed to be adjacent to each other on the isolation region 102. Alternatively, the resistors 21 and 22 may be formed on separate isolation regions 102. The n-FETs 11 and 12 may be p-FETs.

Hereinafter, a method for fabricating a semiconductor device configured as described above will be described with reference to the drawings.

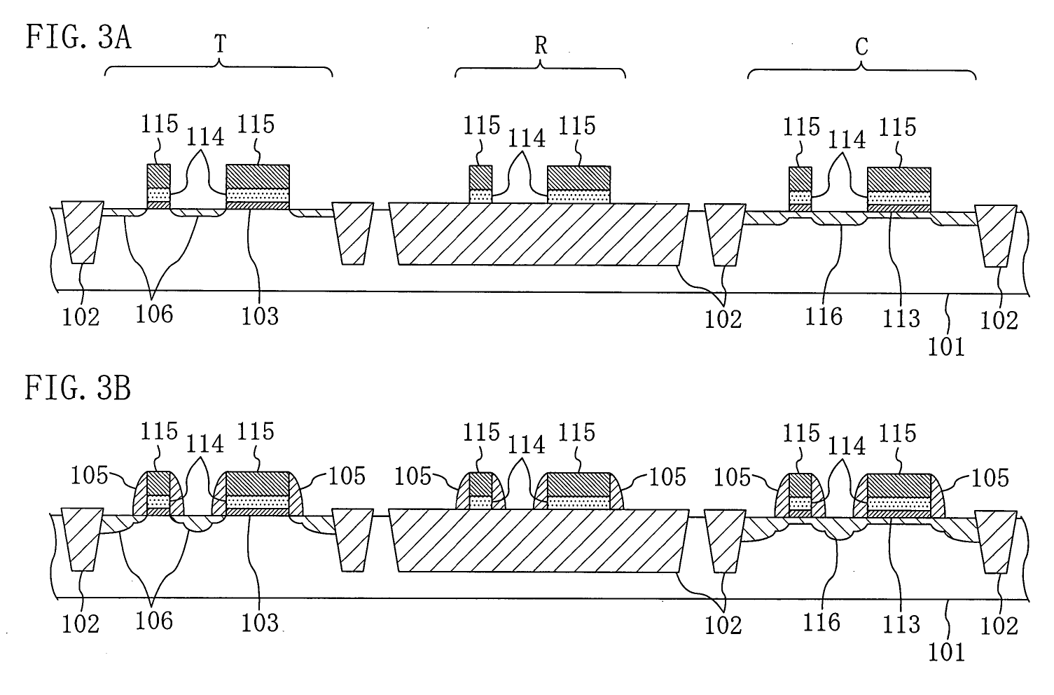

FIGS. 3A and 3B through FIGS. 7A and 7B illustrate cross-sectional structures in respective process steps of a method for fabricating a semiconductor device according to the first embodiment.

First, as illustrated in FIG. 3A, an isolation region 102 is formed in an upper portion of a semiconductor substrate 101 made of silicon. Thereafter, n-type impurity ions, for example, are selectively implanted in a capacitor region C, thereby forming a doped layer to be a part of a lower electrode 116 in an upper portion of the semiconductor substrate 101. This doped layer is to serve as a lower electrode 116 of a capacitor directly under a capacitive insulating film 113. Then, a gate insulating film 103 and an capacitive insulating film 113 are deposited by chemical vapor deposition (CVD) to have a physical thickness of 3 nm over an FET region T and a capacitor region C, respectively, of the principal surface of the semiconductor substrate 101. Subsequently, a polysilicon film 114 with a thickness of 50 nm and a protective insulating film 115 of silicon dioxide (SiO₂) with a thickness of 50 nm are deposited in this order by CVD over the semiconductor substrate 101 with the gate insulating film 103 interposed between the polysilicon film 114 and the semiconductor substrate 101 in the FET region T and the capacitive insulating film 113 interposed between the polysilicon film 114 and the semiconductor substrate 101 in the capacitor region C. The polysilicon film 114 may be made of amorphous silicon. Thereafter, a resist pattern (not shown) masking a gate electrode region of the FET region T, a resistor-element region of the resistor region R and an upper-electrode region of the capacitor region C is formed on the protective insulating film 115 by lithography. Subsequently, patterning is performed with etching using the resist pattern as a mask, thereby forming first and second gate-electrode patterns having different gate lengths out of the protective insulating film 115 and the polysilicon film 114 in the FET region T, forming first and second resistor-element patterns having different widths out of the protective insulating film 115 and the polysilicon film 114 in the resistor region R, and forming first and second upper-electrode patterns having different widths out of the protective insulating film 115 and the polysilicon film 114 in the capacitor region C. For this etching, if dry etching is adopted, an etching gas containing fluorocarbon as a main component is used for silicon oxide and an etching gas containing chlorine as a main component is used for polysilicon. Subsequently, n-type impurity ions are implanted in the semiconductor substrate 101 using the protective insulating film 115 as a mask, thereby forming an extension layer of n-type source/drain regions 106 in the FET region T and forming a portion of the lower electrode 116 in the capacitor region C.

Next, as illustrated in FIG. 3B, a silicon nitride film, for example, is deposited by CVD over the semiconductor substrate 101 to cover the polysilicon film 114 and the protective insulating film 115 and then is etched back, thereby forming sidewall spacers 105 on both sides of each of the polysilicon film 114 and the protective insulating film 115. The sidewall spacers 105 may be a stack of silicon oxide and silicon nitride in which silicon oxide serves as an underlying film. Subsequently, n-type impurity ions are implanted in the semiconductor substrate 101 using the protective insulating film 115 and the sidewall spacers 105 as masks, thereby forming n-type source/drain regions 106 in the FET region T and forming the remaining portion of the lower electrode 116 in the capacitor region C. Thereafter, the exposed surfaces of the n-type source/drain regions 106 and the lower electrode 116 may be silicided with, for example, nickel (Ni).

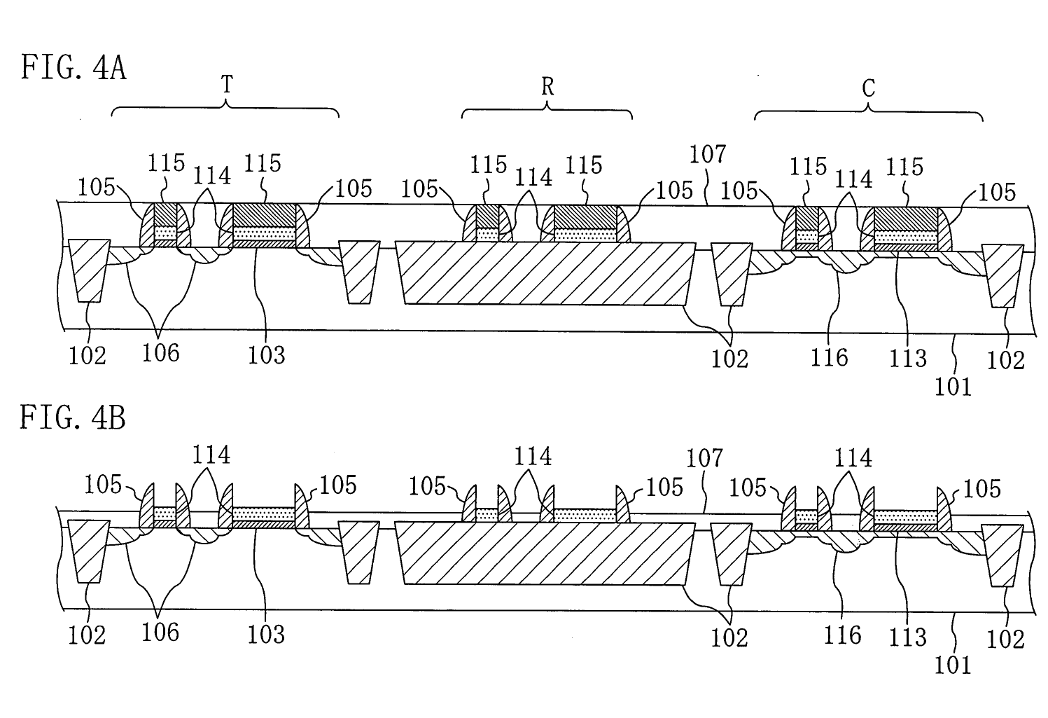

Then, as illustrated in FIG. 4A, an interlayer insulating film 107 made of, for example, silicon oxide, is deposited by CVD over the semiconductor substrate 101 to cover the protective insulating film 115 and the sidewall spacers 105, and then is planarized by, for example, chemical mechanical polishing (CMP), thereby exposing the protective insulating film 115.

Thereafter, as illustrated in FIG. 4B, the protective insulating film 115 is removed by, for example, wet etching, thereby exposing the polysilicon film 114 under the protective insulating film 115. At this time, the height difference between the upper ends of the sidewall spacers 105 and the upper surface of the polysilicon film 114 is larger than the thickness of a metal film for silicidation which will be deposited at a subsequent step. In the first embodiment, both the protective insulating film 115 and the interlayer insulating film 107 are made of silicon oxide, so that the interlayer insulating film 107 is etched simultaneously with the protective insulating film 115. However, even when the interlayer insulating film 107 is etched at the same time, the etching is controlled so as not to expose the semiconductor substrate 101, thus causing no substantial problems. For the protective insulating film 115 and the interlayer insulating film 107, materials or deposition conditions having different etch rates may be used. For example, if phosphorus (P) or boron (B) is added to silicon oxide forming the protective insulating film 115, the etch rate of the protective insulating film 115 is higher than that of the interlayer insulating film 107, so that the selectivity with respect to the interlayer insulating film 107 is obtained. To provide silicon nitride forming the polysilicon film 114 and the sidewall spacers 105 with selectivity with respect to silicon oxide, an etchant containing hydrogen fluoride as a main component may be used in the case of wet etching. In the case of dry etching, reactive ion etching may be used under conditions in which C₅F₈ at a flow rate of 15 ml/min (standard condition), O₂ at a flow rate of 18 ml/min (standard condition) and Ar at a flow rate of 950 ml/min (standard condition) are supplied under a pressure of 6.7 Pa with an RF power (T/B) is 1800 W/1500 W at a substrate temperature of 0° C.

In the first embodiment, the protective insulating film 115 is deposited, and then a height difference between the upper ends of the sidewall spacers 105 and the polysilicon film 114 is formed by etching. However, the protective insulating film 115 is not necessarily formed. Specifically, the height difference may be formed between the upper ends of the sidewall spacers 105 and the polysilicon film 114 by directly depositing the interlayer insulating film 107 on the polysilicon film 114 with no protective insulating film 115 deposited, exposing the upper surface of the polysilicon film 114 by, for example, CMP and then removing the exposed upper portions of the polysilicon film 114 through etching.

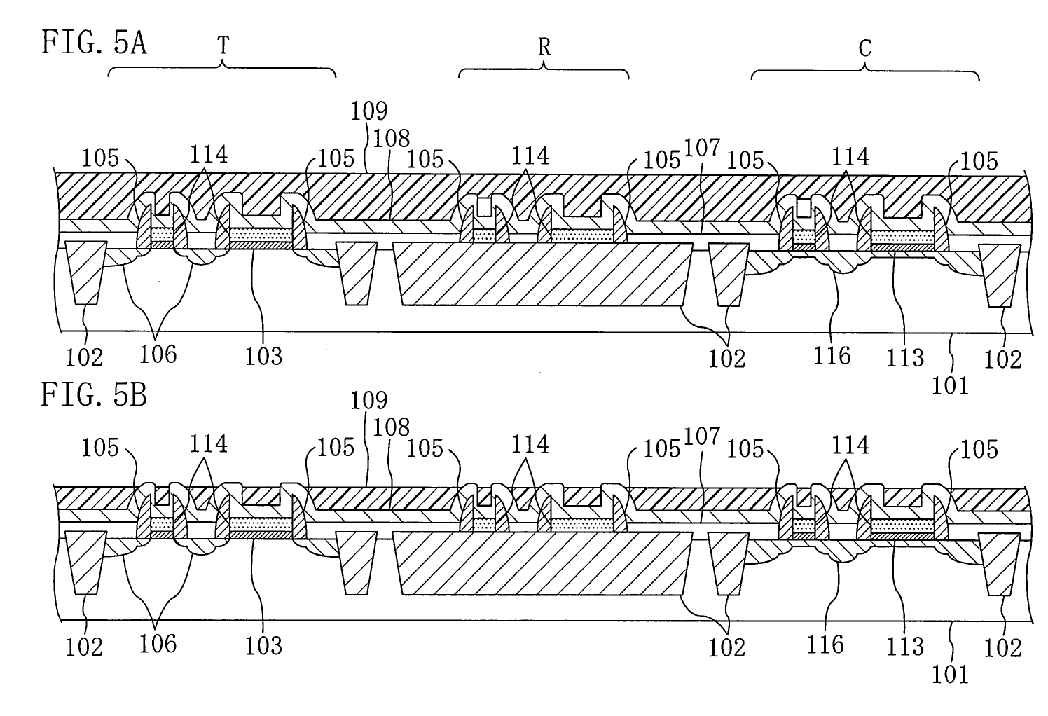

Then, as illustrated in FIG. 5A, a metal film 108 made of nickel (Ni) is deposited by sputtering to a thickness of, for example, 30 nm over the interlayer insulating film 107 including the exposed sidewall spacers 105 and the exposed polysilicon film 114. The deposition of the metal film 108 does not depend on the size of the polysilicon film 114 because of poor step coverage in general, so that trenches are formed in portions of the metal film 108 located on the polysilicon film 114 in cross section, i.e., the portions of the metal film 108 near the sidewall spacers 105 are high and middle portions thereof are low. The width of the trenches is determined in a self-aligned manner depending on the size (planar dimensions) of the polysilicon film 114, as illustrated in FIG. 2. Subsequently, a resist film 109 made of an organic material as a mask member is applied onto the entire surface of the metal film 108 by a spin coating process. In this embodiment, a resist material is used as a mask member, but other materials such as insulating materials may be used instead. It should be noted that in the case of depositing such an insulating material by, for example, CVD, the material is deposited at a high temperature in general. Accordingly, silicidation can proceed between the polysilicon film 114 and the metal film 108 during deposition of the mask member by, for example, CVD. However, no substantial problems arise as long as the silicidation stops when or before the upper surface of the metal film 108 is silicided. However, since the material can be deposited at low temperature, an organic material or an organic oxide film is preferably formed by a coating process.

Thereafter, as illustrated in FIG. 5B, the resist film 109 is etched back, thereby exposing portions of the metal film 108 located on the upper ends of the sidewall spacers 105. At this time, the width of the trench portions of the metal film 108 on the polysilicon film 114 is determined in a self-aligned manner according to the planar dimensions of the polysilicon film 114. Accordingly, the width of the resist material remaining in the trenches is also determined in a self-aligned manner. In this case, the metal film 108 also remains over the n-type source/drain regions 106, the lower electrode 116 and the isolation region 102. However, the interlayer insulating film 107 is interposed between the metal film 108 and each of the n-type source/drain regions 106, the lower electrode 116 and the isolation region 102, so that excessive silicidation does not occur in the n-type source/drain regions 106 and the lower electrode 116.

In the first embodiment, etch back is used to expose the portions of the metal film 108 on the upper ends of the sidewall spacers 105. However, other methods such as CMP may be used.

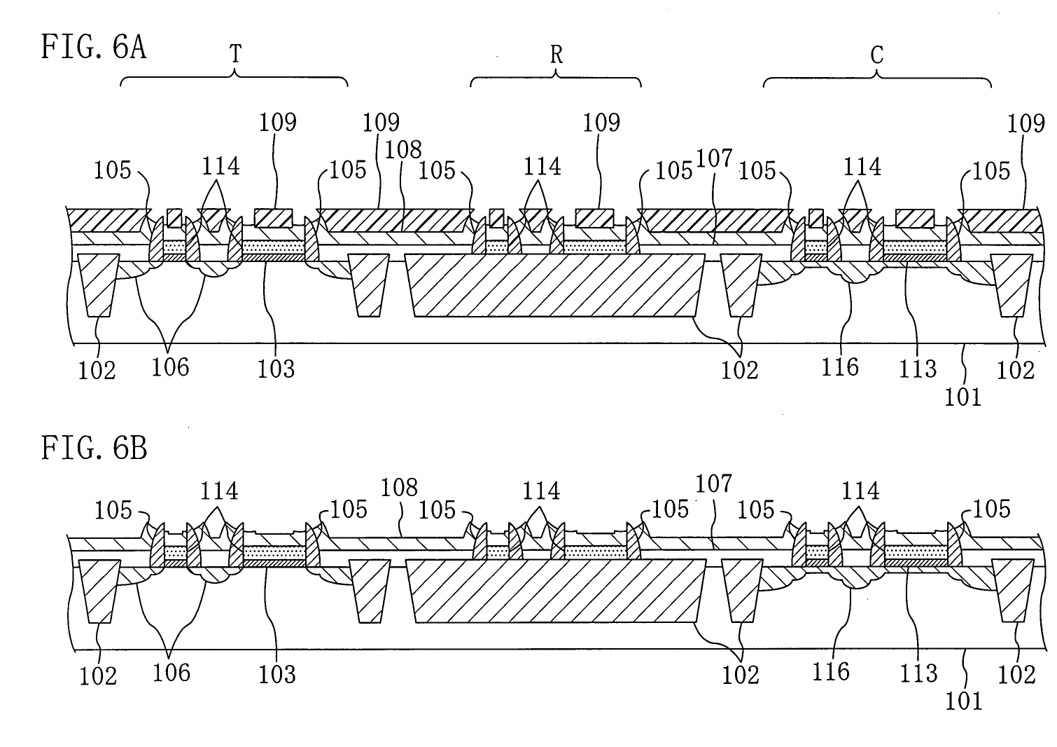

Subsequently, as illustrated in FIG. 6A, the metal film 108 is wet etched with a solution in which hydrochloric acid and a hydrogen peroxide solution, for example, are mixed using the etched-back resist film 109 as a mask. This etching is performed until portions of the metal film 108 on the sidewall spacers 105 are partially removed so that the upper ends of the sidewall spacers 105 are exposed. Accordingly, though the metal film 108 remains on lower portions of the side faces of the resist film 109, no substantial problems occur.

Then, as illustrated in FIG. 6B, the resist film 109 is removed by, for example, ashing using oxygen plasma. In this manner, if the resist film 109 is made of an organic material as described above, this organic material serves as an impurity during, for example, heat treatment in a subsequent step, so that the resist film 109 needs to be removed. However, if a so-called hard mask made of an insulating material such as a silicon oxide film is used instead of the resist film 109, this hard mask does not need to be removed.

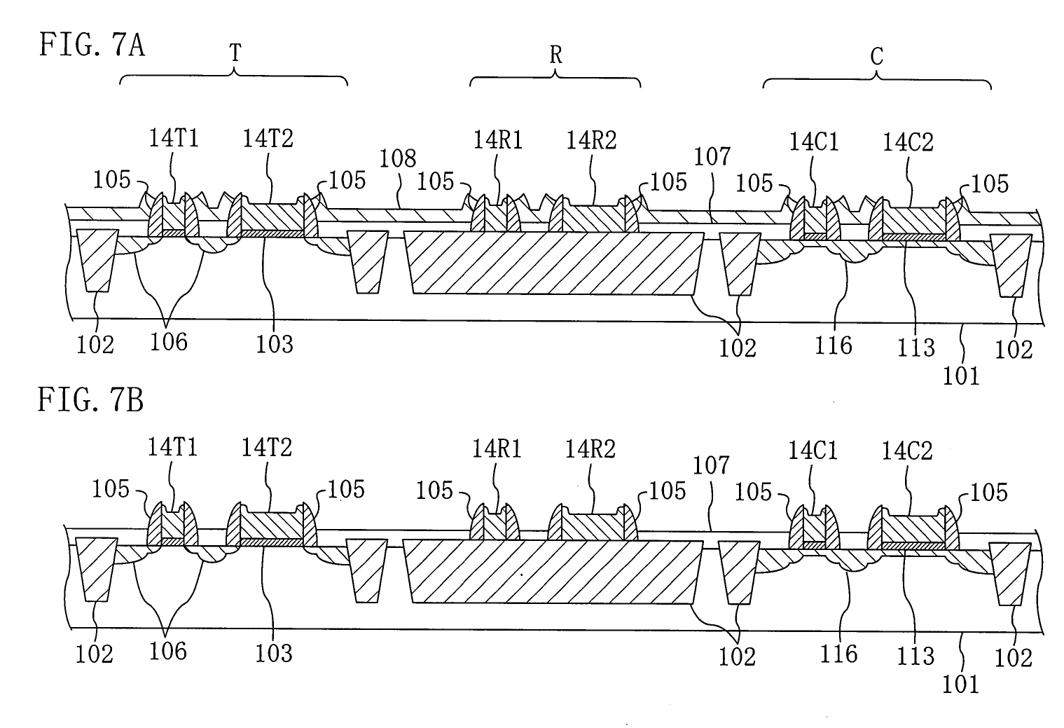

Thereafter, as illustrated in FIG. 7A, heat treatment is performed on the semiconductor substrate 101 by, for example, rapid thermal annealing (RTA) at 400° C. in a nitrogen atmosphere to cause silicidation between the polysilicon film 114 and the metal film 108, thereby siliciding the entire polysilicon film 114. In this manner, a first gate electrode 14T1 and a second gate electrode 14T2 both having FUSI structures and having different gate lengths are formed in the FET region T of the semiconductor substrate 101, a first resistor element 14R1 and a second resistor element 14R2 both having FUSI structures and having different widths are formed in the resistor region R, and a first upper electrode 14C1 and a second upper electrode 14C2 both having FUSI structures and having different widths are formed in the capacitor region C.

The first embodiment is characterized in that portions of the metal film 108 located on the upper ends of the sidewall spacers 105 are removed in the silicidation step, so that portions of the metal film 108 on the polysilicon film 114 are isolated from each other. This prevents metal from being excessively supplied from portions on the upper ends of the sidewall spacers 105 and their neighboring portions. Accordingly, the volume ratio between portions of the polysilicon film 114 capable of reacting and portions of the metal film 108 capable of reacting does not depend on the gate lengths, i.e., the planar dimensions, of the gate electrodes 14T1 and 14T2, for example. Specifically, the volume ratio between the reactable portions of the polysilicon film 114 and the reactable portions of the metal film 108 is determined by the thickness of the polysilicon film 114 exposed in the process step shown in FIG. 4B and the thickness of the metal film 108 deposited in the process step shown in FIG. 5A, and is substantially uniform. In other words, silicidation in the polysilicon film 114 transitions from reaction-limited to supply-limited. In this manner, even the gate electrodes 14T1 and 14T2, the resistor elements 14R1 and 14R2 and the upper electrodes 14C1 and 14C2 having different planar dimensions are allowed to have FUSI structures with a uniform composition. Since each of the isolated portions of the metal film 108 has a recess shape in cross section in the gate length direction (width direction), each of the gate electrodes 14T1 and 14T2, the resistor elements 14R1 and 14R2 and the upper electrodes 14C1 and 14C2 also has a recess shape in cross section in the gate length direction (width direction). In addition, no silicidation occurs in portions of the metal film 108 over the n-type source/drain regions 106, the lower electrode 116 and the isolation region 102 because the interlayer insulating film 107 is interposed therebetween.

Then, as illustrated in FIG. 7B, the unreacted portions of the metal film 108 remaining above the n-type source/drain regions 106, for example, are removed by etching using a solution in which hydrochloric acid and a hydrogen peroxide solution, for example, are mixed. Thereafter, an upper-level interlayer insulating film is deposited over the interlayer insulating film 107 including the FUSI gate electrodes 14T1 and 14T2 and other components, thereby forming contact holes and interconnections.

As described above, with the method for fabricating a semiconductor device according to the first embodiment, the sidewall spacers 105 are formed on the sides of the polysilicon film 114 before silicidation, and then the upper surface of the polysilicon film 114 is lowered so that a height difference is formed between the upper ends of the sidewall spacers 105 and the polysilicon film 114. In this manner, during deposition of the metal film 108 over the polysilicon film 114, trenches are formed in upper portions of the gate electrodes and the resistor elements in a self-aligned manner according to the planar dimensions of the gate electrodes and the resistor elements. Accordingly, the resist film 109 according to the gate lengths (widths) is formed in a self-aligned manner. Specifically, even if the gate electrode 14T1 has a relatively small gate length as in the first n-FET 11, recess shapes are transferred to the metal film 108 and further to the resist film 109 deposited between the opposing sidewall spacers 105. This enables selective removal of only portions of the metal film 108 located on the sidewall spacers 105, so that portions of the metal film 108 remaining on the polysilicon film 114 are isolated from each other. As a result, the gate electrodes 14T1 and 14T2 have the same FUSI structure, irrespective of the gate lengths.

With the method of the first embodiment, the first n-FET 11, the second n-FET 12, the first resistor 21, the second resistor 22, the first capacitor 31 and the second capacitor 32 having the same uniform FUSI structure are formed at a time on the single semiconductor substrate 101.

The n-FETs 11 and 21 are formed in the FET region T, but p-FETs may be formed instead.

The gate insulating film 103 and the capacitive insulating film 113 are made of HfO₂, but may be made of HfSiO, HfSiON, SiO₂ or SiON, for example. In this embodiment, the gate insulating film 103 and the capacitive insulating film 113 are formed in the same process step, but may be formed in different process steps.

Embodiment 2

Hereinafter a second embodiment of the present invention will be described with reference to the drawings.

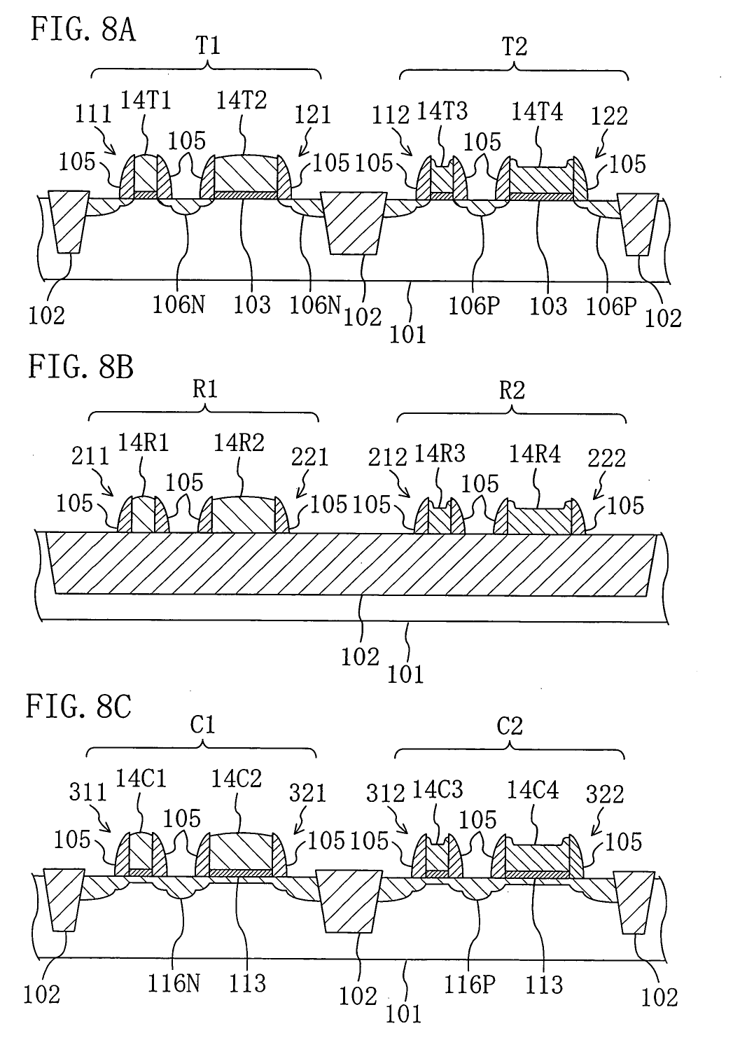

FIGS. 8A through 8C illustrate cross sectional structures of a semiconductor device according to the second embodiment. In FIGS. 8A through 8C, components also shown in FIG. 1 are denoted by the same reference numerals and description thereof will be omitted. The semiconductor device of this embodiment are divided into portions illustrated in FIGS. 8A through 8C for convenience, but is actually formed on one semiconductor substrate 101.

As illustrated in FIGS. 8A through 8C, the semiconductor device of the second embodiment includes: an n-FET region T1; a p-FET region T2; a first resistor region RI; a second resistor region R2; a first capacitor region C1; and a second capacitor region C2, as a plurality of device regions defined by an isolation region 102 selectively formed in an upper portion of the semiconductor substrate 101. The resistor regions R1 and R2 are formed on the isolation region 102.

As illustrated in FIG. 8A, a first n-FET 111 and a second n-FET 121 having different gate lengths are formed in the n-FET region T1. A first p-FET 112 and a second p-FET 122 having different gate lengths are formed in the p-FET region T2.

As illustrated in FIG. 8B, a first resistor 211 and a second resistor 221 having different widths are formed in the first resistor region R1, and a third resistor 212 and a fourth resistor 222 having different widths are formed in the second resistor region R2.

As illustrated in FIG. 8C, a first capacitor 311 and a second capacitor 321 having different widths are formed in the first capacitor region C1. A third capacitor 312 and a fourth capacitor 322 having different widths are formed in the second capacitor region C2.

Each of the first n-FET 111 and the second n-FET 121 in the n-FET region T1 includes: a gate insulating film 103 formed on the semiconductor substrate 101; a first gate electrode 14T1 formed on the gate insulating film 103 and made of FUSI NiSi or a second gate electrode 14T2 formed on the gate insulating film 103, made of FUSI NiSi and having a gate length larger than that of the first gate electrode 14T1; sidewall spacers 105 formed on both sides of the gate electrode 14T1 or 14T2; and n-type source/drain regions 106N formed below the gate electrode 14T1 or 14T2 in the semiconductor substrate 101.

Each of the first p-FET 112 and the second p-FET 122 in the p-FET region T2 includes: a gate insulating film 103 formed on the semiconductor substrate 101; a third gate electrode 14T3 formed on the gate insulating film 103 and made of FUSI Ni₃Si or a fourth gate electrode 14T4 formed on the gate insulating film 103, made of FUSI Ni₃Si and having a gate length larger than that of the third gate electrode 14T3; sidewall spacers 105 formed on both sides of the gate electrode 14T3 or 14T4; and p-type source/drain regions 106P formed below the gate electrode 14T3 or 14T4 in the semiconductor substrate 101.

Each of the first resistor 211 and the second resistor 221 in the first resistor region R1 includes: a first resistor element 14R1 made of FUSI NiSi or a second resistor element 14R2 made of FUSI NiSi and having a width larger than that of the first resistor element 14R1; and sidewall spacers 105 formed on both sides of the resistor element 14R1 or 14R2.

Each of the third resistor 212 and the fourth resistor 222 in the second resistor region R2 includes: a third resistor element 14R3 made of FUSI Ni₃Si or a fourth resistor element 14R4 made of FUSI Ni₃Si and having a width larger than that of the third resistor element 14R3; and sidewall spacers 105 formed on both sides of the resistor element 14R3 or 14R4.

The first capacitor 311 and the second capacitor 321 in the first capacitor region C1 are MIS capacitors. Each of the first capacitor 311 and the second capacitor 321 includes: a capacitive insulating film 113 formed on the semiconductor substrate 101; a first upper electrode 14C1 formed on the capacitive insulating film 113 and made of FUSI NiSi and a second upper electrode 14C2 formed on the capacitive insulating film 113, made of FUSI NiSi and having a width larger than that of the first upper electrode 14C1; sidewall spacers 105 formed on both sides of the upper electrode 14C1 or 14C2; and an n-type lower electrode 116N formed below the upper electrode 14C1 or 14C2 and under the capacitive insulating film 113 in the semiconductor substrate 101 and doped with n-type impurity ions.

The third capacitor 312 and the fourth capacitor 322 in the second capacitor region C2 are MIS capacitors. Each of the third capacitor 312 and the fourth capacitor 322 includes: a capacitive insulating film 113 formed on the semiconductor substrate 101; a third upper electrode 14C3 formed on the capacitive insulating film 113 and made of FUSI Ni₃Si and a fourth upper electrode 14C4 formed on the capacitive insulating film 113, made of FUSI Ni₃Si and having a width larger than that of the third upper electrode 14C3; sidewall spacers 105 formed on both sides of the upper electrode 14C3 or 14C4; and a p-type lower electrode 116P formed below the upper electrode 14C3 or 14C4 and under the capacitive insulating film 113 in the semiconductor substrate 101 and doped with p-type impurity ions.

In this manner, in the semiconductor device of the second embodiment, the composition of nickel silicide (Ni composition) differs between the first and second gate electrodes 14T1 and 14T2 and the third and fourth gate electrodes 14T3 and 14T4 in the n-FET region T1 and the p-FET region T2, respectively. In addition, each of the gate electrodes 14T3 and 14T4 in the p-FET region T2 has a recess shape which is high in both ends and is low in the middle in the gate length direction, and the width of the recess depends on the sizes of the gate electrodes 14T3 and 14T4. On the other hand, each of the gate electrodes 14T1 and 14T2 in the n-FET region T1 has a convex shape which is high in the middle in the gate length direction in cross section. As specifically described in a fabrication method which will be described below, the convex shape in cross section is formed because of the following reasons. Since the composition of the gate electrodes 14T1 and 14T2 is NiSi, the thickness of the polysilicon film for forming gates is larger than that in the p-FET region T2 in order to make the silicon (Si) content higher than that of Ni₃Si, i.e., the composition of the gate electrodes 14T3 and 14T4 in the p-FET region T2.

Accordingly, in the first resistor region RI and the first capacitor region C1 formed in the same manner as the n-FET region T1, each of the FUSI resistor elements 14R1 and 14R2 and the FUSI upper electrodes 14C1 and 14C2 has a convex shape in the width direction in cross section. On the other hand, in the second resistor region R2 and the second capacitor region C2 formed in the same manner as the p-FET region T2, each of the metal-rich FUSI resistor elements 14R3 and 14R4 and the metal-rich FUSI upper electrodes 14C3 and 14C4 has a recess shape in cross section in the width direction. In this case, the width of each recess depends on the width of an associated one of the resistor elements 14R3 and 14R4 and the upper electrodes 14C3 and 14C4.

In addition, in the semiconductor device of the second embodiment, as in the first embodiment, the first and second gate electrodes 14T1 and 14T2, the first and second resistor elements 14R1 and 14R2 and the first and second upper electrodes 14C1 and 14C1 do not depend on the sizes (planar dimensions) thereof and have an identical composition in a self-aligned manner. In the same manner, the third and fourth gate electrodes 14T3 and 14T4, the third and fourth resistor elements 14R3 and 14R4 and the third and fourth upper electrodes 14C3 and 14C4 do not depend on the sizes (planar dimensions) thereof and have an identical composition in a self-aligned manner.

Accordingly, in the n-FET 111 and 121 and the p-FET 112 and 122, variation of the threshold voltage due to nonuniformity of the composition depending on the sizes of the gate electrodes 14T1 and 14T2 is prevented. As a result, performance of the semiconductor device is enhanced and integration degree is increased.

In the resistors 211 through 222 and the capacitors 311 through 322, variations of the resistance value and the capacitance value are prevented.

In FIGS. 8A through 8C, each pair of the n-FETs 111 and 121, the p-FETs 112 and 122, the capacitors 311 and 321, and the capacitors 312 and 322 are formed in the same region and the resistors 211, 221, 212, 222 are formed in the same region of the semiconductor substrate 101 defined by the isolation region 102, as an example. However, these devices may be individually formed in different regions defined by the isolation region 102, or two types of these components may be formed in the same region. The resistors 211, 221, 212 and 222 are formed to be adjacent to each other on the isolation region 102. Alternatively, the resistors may be formed on respective separate isolation regions 102. In a configuration provided with the n-FETs 111 and 121 and the p-FETs 112 and 122, the compositions of all the gate electrodes 14T1 through 14T4 may be Ni₃Si.

Hereinafter, a method for fabricating a semiconductor device configured as described above will be described with reference to the drawings.

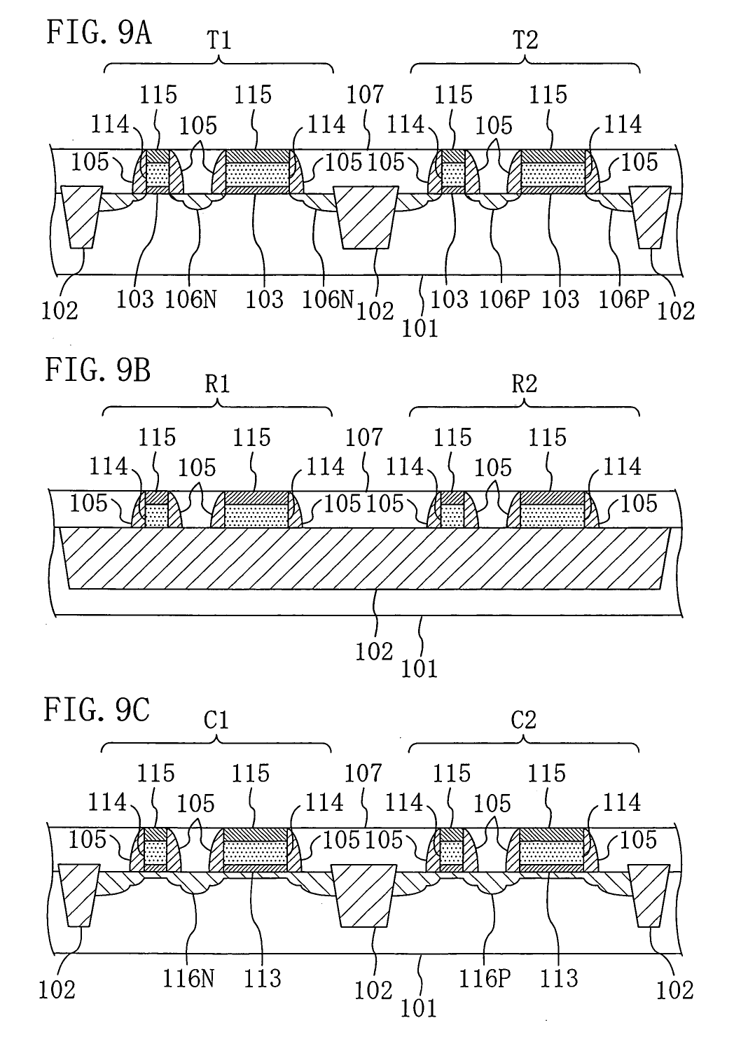

FIGS. 9A through 9C to FIGS. 16A through 16C illustrate cross-sectional structures in respective process steps of a method for fabricating a semiconductor device according to the second embodiment.

First, as illustrated in FIGS. 9A through 9C, as in the first embodiment, an isolation region 102 is selectively formed in an upper portion of a semiconductor substrate 101 made of silicon. Subsequently, an n-type impurity is selectively implanted in a first capacitor region C1 of the semiconductor substrate 101, thereby forming a part of an n-type lower electrode 116N. A p-type impurity is selectively implanted in a second capacitor region C2 of the semiconductor substrate 101, thereby forming a part of a p-type lower electrode 116P. Thereafter, a gate insulating film 103 and a capacitive insulating film 113 both made of, for example, HfO₂ are deposited by CVD over the principal surface of the semiconductor substrate 101. Subsequently, a polysilicon film 114 having a thickness of 50 nm and a protective insulating film 115 having a thickness of 50 nm and made of silicon oxide are deposited in this order by CVD over the semiconductor substrate 101 with the gate insulating film 103 interposed between the polysilicon film 114 and the semiconductor substrate 101 in the n-FET region T1 and the p-FET region T2 and the capacitive insulating film 113 interposed between the polysilicon film 114 and the semiconductor substrate 101 in the first capacitor region C1 and the second capacitor region C2. Thereafter, the protective insulating film 115 and the polysilicon film 114 are patterned by lithography and etching, thereby forming first and second gate-electrode patterns having different gate lengths and forming third and fourth gate-electrode patterns having different gate lengths in the n- and p-FET regions T1 and T2. In the first and second resistor regions R1 and R2, the first and second resistor patterns having different widths and the third and fourth resistor patterns having different widths are formed. In the first and second capacitor regions C1 and C2, the first and second upper-electrode patterns having different widths and third and fourth upper-electrode patterns having different widths are formed. Subsequently, n-type source/drain regions 106N and an n-type lower electrode 116N are partly formed in the n-FET region T1 and the first capacitor region C1, respectively. Thereafter, p-type source/drain regions 106P and a p-type lower electrode 116P are partly formed in the p-FET region T2 and the second capacitor region C2, respectively. The order of the step of implanting n-type impurity ions and the step of implanting p-type impurity ions is not limited. Subsequently, sidewall spacers 105 of silicon nitride are formed on both sides of each of the polysilicon film 114 and the protective insulating film 115. Thereafter, using the protective insulating film 115 and the sidewall spacers 105 as masks, the remaining portions of the n-type source/drain regions 106N and the remaining portion of the n-type lower electrode 116N are formed. Then, the remaining portion of the p-type source/drain regions 106P and the remaining portion of the p-type lower electrode 116P are formed. Thereafter, the exposed surfaces of the n-type source/drain regions 106N, the p-type source/drain regions 106P, the n-type lower electrode 116N and the p-type lower electrode 116P may be silicided with nickel (Ni), for example. Then, an interlayer insulating film 107 made of silicon oxide is deposited by CVD over the semiconductor substrate 101 to cover the protective insulating film 115 and the sidewall spacers 105. Then, the upper surface of the interlayer insulating film 107 is planarized, thereby exposing the protective insulating film 115.

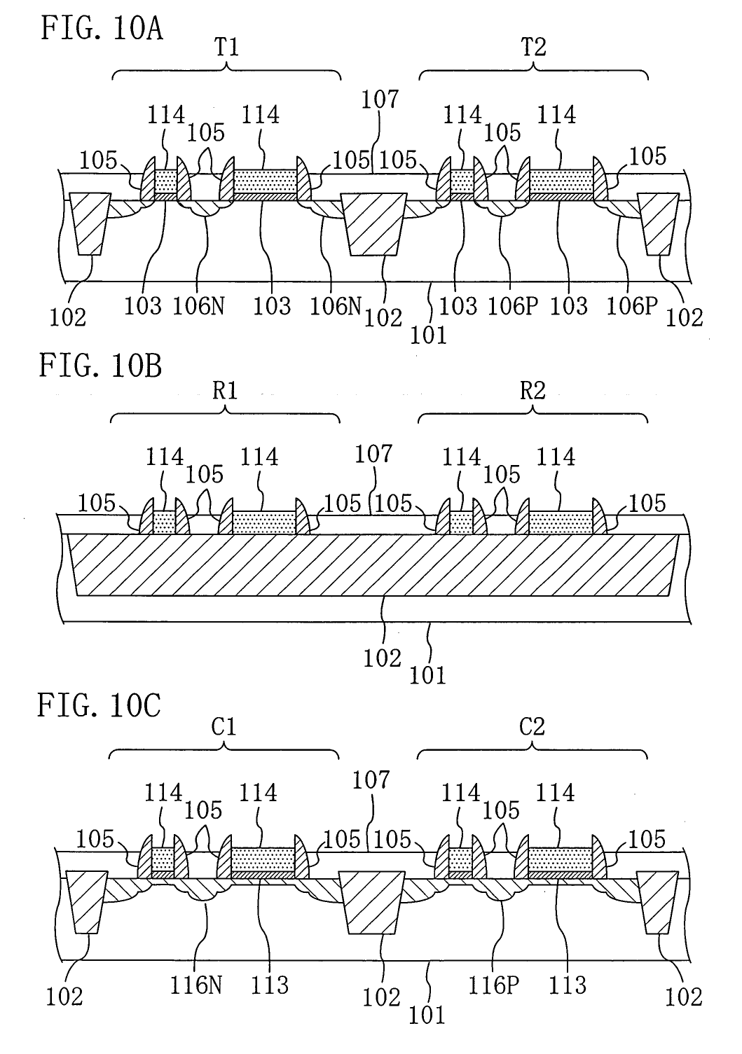

Then, as illustrated in FIGS. 10A through 10C, the protective insulating film 115 on the polysilicon film 114 in the FET regions T1 and T2, the resistor regions R1 and R2 and the capacitor regions C1 and C2 are removed by, for example, wet etching, thereby exposing the polysilicon film 114 under the protective insulating film 115. At this time, the height difference between the upper ends of the sidewall spacers 105 and the upper surface of the polysilicon film is larger than the thickness of a metal film for silicidation to be deposited in a subsequent process step. In the second embodiment, instead of depositing the protective insulating film 115 on the polysilicon film 114, the height difference may also be formed between the upper ends of the sidewall spacers 105 and the polysilicon film 114 by directly depositing the interlayer insulating film 107, exposing the upper surface of the polysilicon film 114 by, for example, CMP, and then removing the exposed upper portions of the polysilicon film 114 with etching.

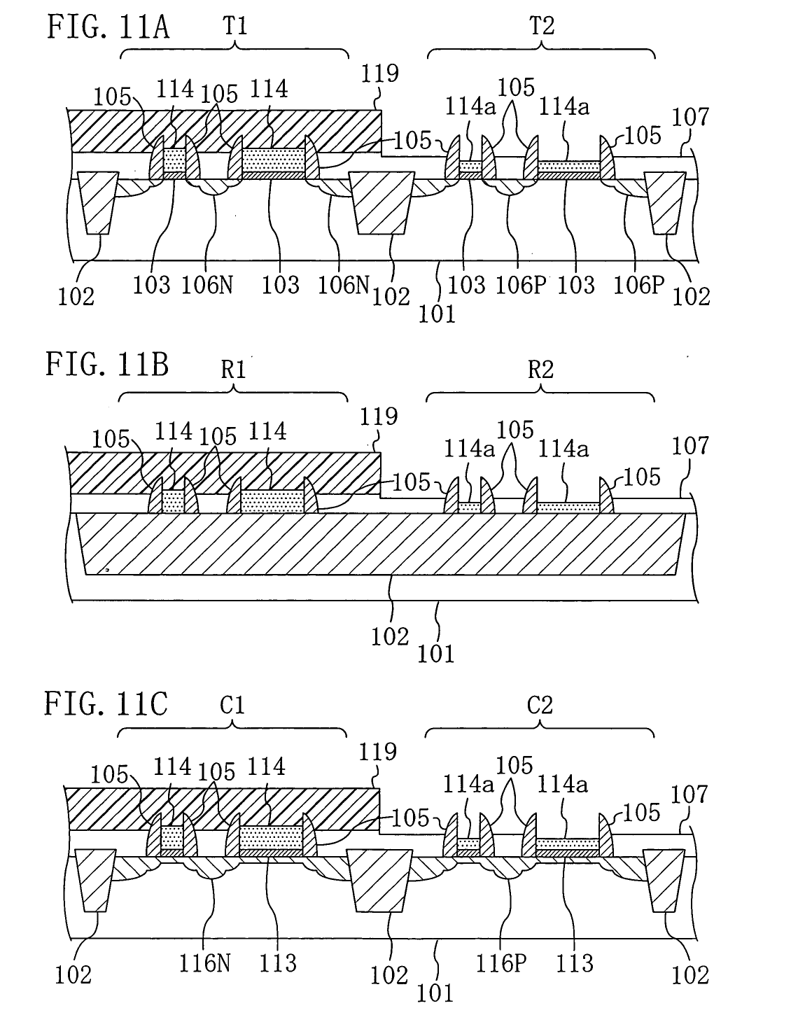

Thereafter, as illustrated in FIGS. 11A through 11C, a first resist film 119 masking the n-FET region T1, the first resistor region R1 and the first capacitor region C1 is formed by lithography. Then, dry etching is performed on portions of the polysilicon film 114 in the p-FET region T2, the second resistor region R2 and the second capacitor region C2 using an etching gas containing chlorine or hydrogen bromide as a main component with the first resist film 119 used as a mask, thereby obtaining a polysilicon film 114a with a thickness of 25 nm.

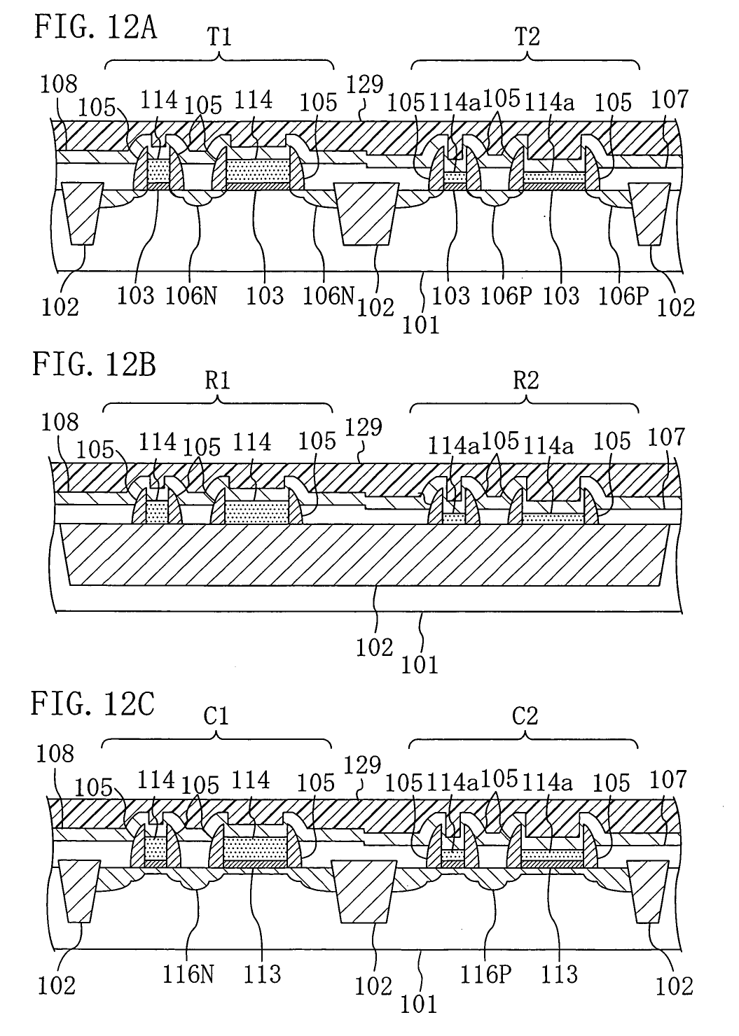

Subsequently, as illustrated in FIGS. 12A through 12C, the first resist film 119 is removed by ashing. Then, a metal film 108 made of nickel (Ni) and having a thickness of 30 nm, for example, is deposited by sputtering over the interlayer insulating film 107 including the exposed sidewall spacers 105 and the polysilicon films 114 and 114a. At this time, as described above, the deposition of the metal film 108 does not depend on the sizes of the polysilicon films 114 and 114a because of poor step coverage, so that trenches are formed in portions of the metal film 108 located on the polysilicon films 114 and 114a in cross section, i.e., the metal film 108 is high near the sidewall spacers 105 and is low in the middle in cross section. The width of the trenches is determined in a self-aligned manner according to the sizes (planar dimensions) of the polysilicon films 114 and 114a. Subsequently, the entire surface of the metal film 108 is coated with a second resist film 129 of an organic material as a mask member. The resist member used as a mask member may be replaced with, for example, an insulating material such as silicon oxide.

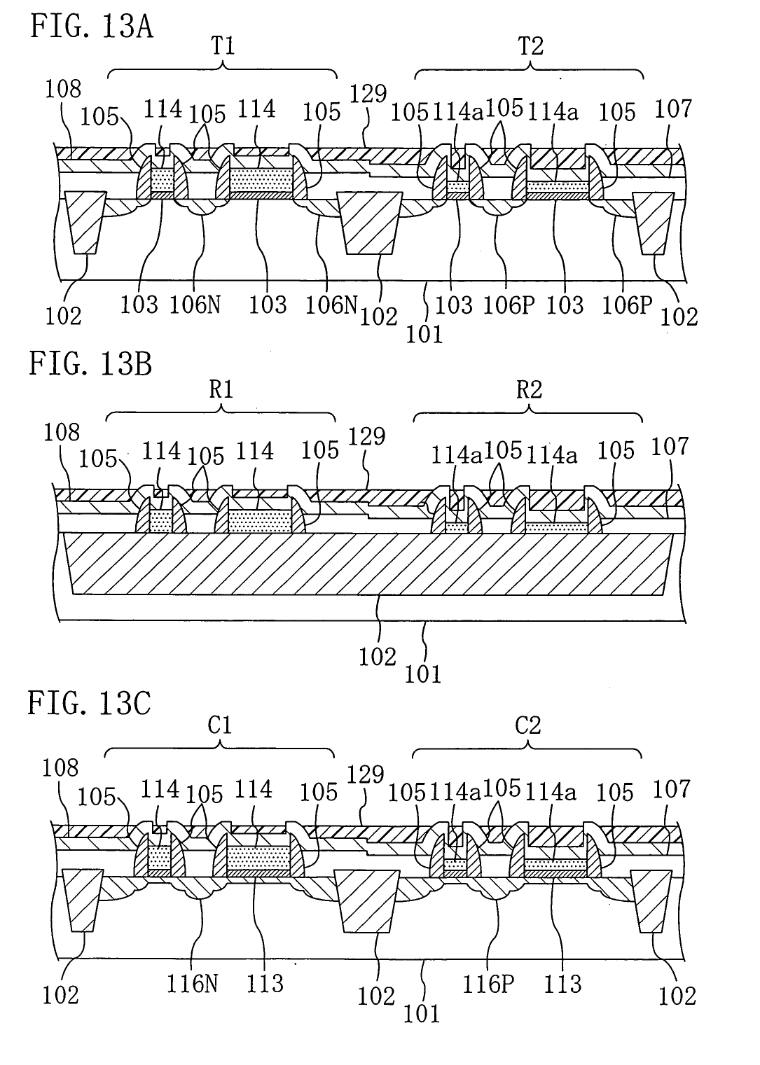

Thereafter, as illustrated in FIGS. 13A through 13C, the second resist film 129 is etched back, thereby exposing portions of the metal film 108 on the upper ends of the sidewall spacers 105. At this time, the width of the trenches formed in portions of the metal film 108 on the polysilicon films 114 and 114a is determined in a self-aligned manner according to the planar dimensions of the polysilicon films 114 and 114a, so that the width of the resist material remaining in the trenches is also determined in a self-aligned manner. At this time, the metal film 108 also remains over the n- and p-type source/drain regions 106N and 106P, n- and p-type lower electrodes 116N and 116P and the isolation region 102, but the interlayer insulating film 107 is interposed between the metal film 108 and these regions and electrodes, so that excessive silicidation of the source/drain regions 106N and 106P and lower electrodes 116N and 116P is prevented. Etch-back is not necessarily used to expose the portions of the metal film 108 covering the upper ends of the metal film 108 but other methods such as CMP may be used.

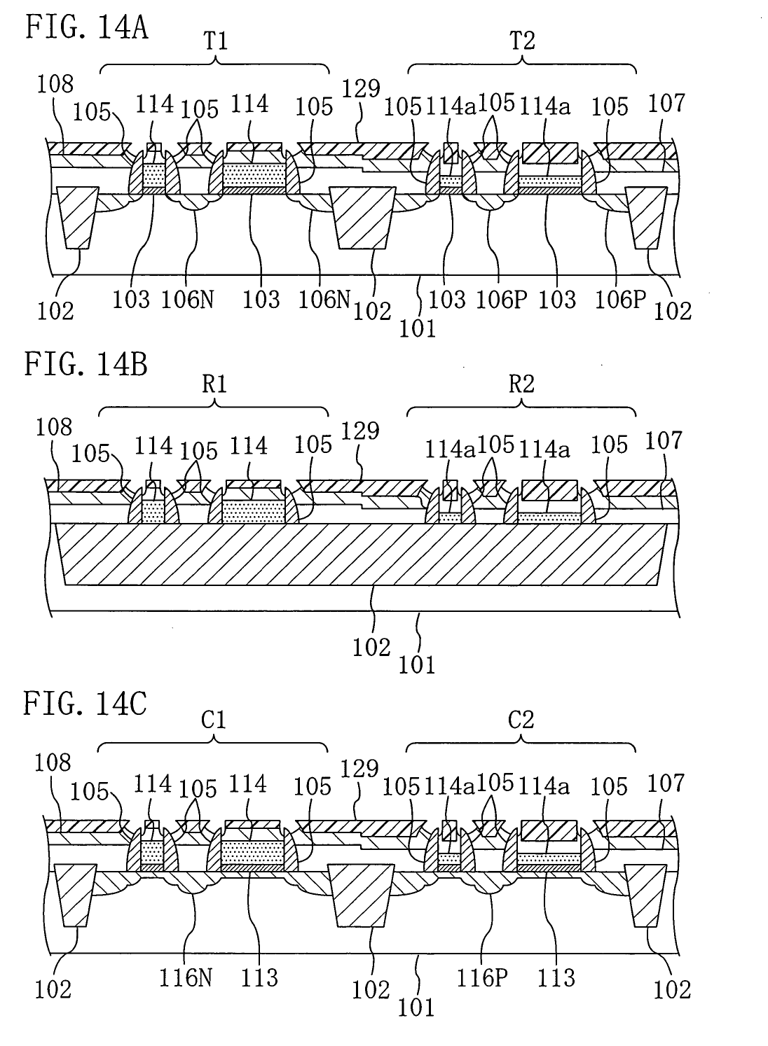

Subsequently, as illustrated in FIGS. 14A through 14C, using the etched-back second resist film 129 as a mask, wet etching is performed on the metal film 108 with a solution in which hydrochloric acid and a hydrogen peroxide solution, for example, are mixed. This etching is performed until portions of the metal film 108 on the upper ends of the sidewall spacers 105 are removed and the upper ends of the sidewall spacers 105 are exposed. At this time, in view of controllability of silicidation in a subsequent process step, the metal film 108 is preferably etched to the bottom of the second resist film 129 because the thickness ratio between the polysilicon film 114 and the metal film 108 greatly affects the silicide compositions in the n-FET region T1, the first resistor region R1 and the first capacitor region C1, for example. On the other hand, in the p-FET region T2, the second resistor region R2 and the second capacitor region C2, the metal film 108 has a large thickness according to the reduction of the thickness of the polysilicon film 114a, the metal film 108 remains on lower portions of the side faces of the second resist film 129, no substantial problem occurs.

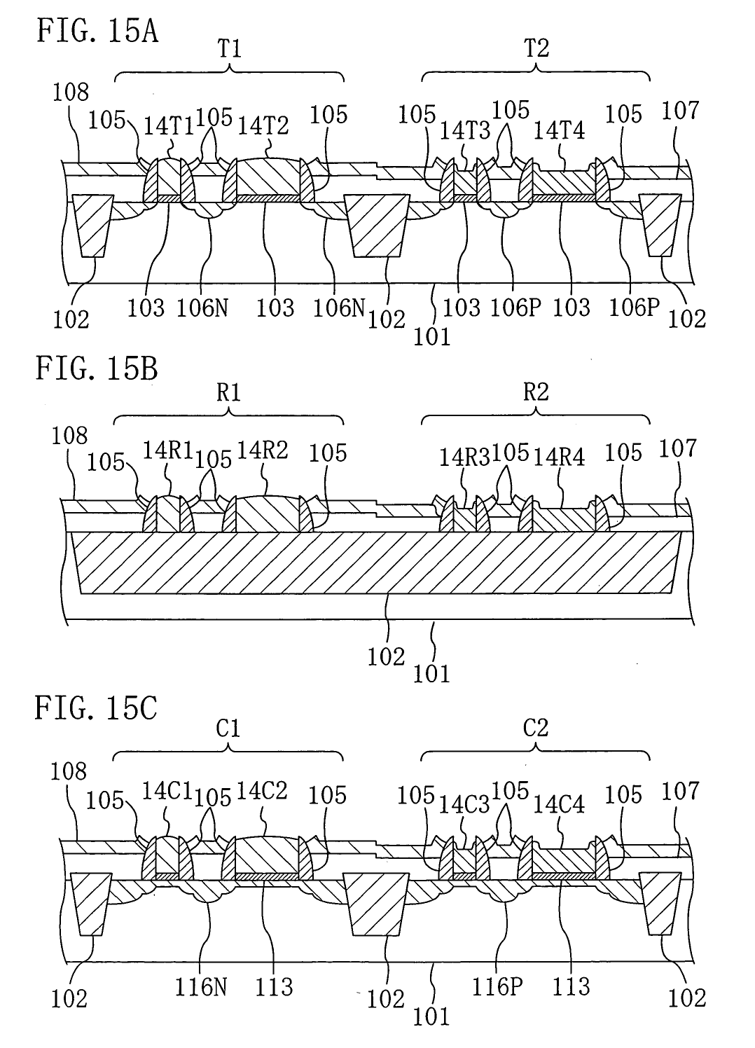

Then, as illustrated in FIGS. 15A through 15C, the second resist film 129 is removed by, for example, ashing. In this manner, if the second resist film 129 is made of an organic material, this organic material serves as an impurity during, for example, heat treatment in a subsequent step, so that the second resist film 129 needs to be removed. However, if a hard mask such as a silicon oxide film is used instead of the second resist film 129, this hard mask does not need to be removed. Thereafter, heat treatment is performed on the semiconductor substrate 101 by, for example, RTA at 400° C. in a nitrogen atmosphere to cause silicidation between the polysilicon films 114 and 114a and the metal film 108, thereby siliciding the entire polysilicon films 114 and 114a. In this manner, a first gate electrode 14T1 and a second gate electrode 14T2 both having FUSI structures of NiSi and having different gate lengths are formed in the n-FET region T1 on the semiconductor substrate 101, a first resistor element 14R1 and a second resistor element 14R2 both having FUSI structures of NiSi and having different widths are formed in the first resistor region R1 on the semiconductor substrate 101, and a first upper electrode 14C1 and a second upper electrode 14C2 both having FUSI structures of NiSi and having different widths are formed in the first capacitor region C1 on the semiconductor substrate 101. On the other hand, a third gate electrode 14T3 and a fourth gate electrode 14T4 both having FUSI structures of Ni₃Si and having different gate lengths are formed in the p-FET region T2 on the semiconductor substrate 101, a third resistor element 14R3 and a fourth resistor element 14R4 both having FUSI structures of Ni₃Si and having different widths are formed in the second resistor region R2 on the semiconductor substrate 101, and a third upper electrode 14C3 and a fourth upper electrode 14C4 both having FUSI structures of Ni₃Si and having different widths are formed in the second capacitor region C2 on the semiconductor substrate 101.

The second embodiment is characterized in that portions of the metal film 108 located on upper ends of the sidewall spacers 105 are removed in the silicidation step, so that portions of the metal film 108 are isolated from each other on the polysilicon films 114 and 114a. This prevents metal from being excessively supplied from portions on upper ends of the sidewall spacers 105 and their neighboring portions. Accordingly, the volume ratio between portions of the polysilicon films 114 and 114a capable of reacting and portions of the metal film 108 capable of reacting does not depend on the gate lengths, i.e., the planar dimensions, of the gate electrodes 14T1 through 14T4. Specifically, the volume ratio between the reactable portions of the polysilicon films 114 and 114a and the reactable portions of the metal film 108 is determined by the thickness of the polysilicon films 114 and 114a exposed in the process steps shown in FIGS. 10A through 10C and FIGS. 11A through 11C and the thickness of the metal film 108 deposited in the process steps shown in FIGS. 12A through 12C, and is substantially uniform. In this manner, even the gate electrodes 14T1 and 14T2, 14T3 and 14T4, the resistor elements 14R1 and 14R2, 14R3 and 14R4, and the upper electrodes 14C1 and 14C2, 14C3 and 14C4, each pair of which has different planar dimensions, are allowed to have FUSI structures with a uniform composition. Since each of the isolated portions of the metal film 108 has a recess shape in cross section in the gate length direction (width direction), each of the gate electrodes 14T3 and 14T4, the resistor elements 14R3 and 14R4 and the upper electrodes 14C3 and 14C4 also has a recess shape in cross section in the gate length direction (width direction). In addition, no silicidation occurs in portions of the metal film 108 deposited over the n- and p-type source/drain regions 106N and 106P, the n- and p-type lower electrodes 116N and 116P and the isolation region 102 because the interlayer insulating film 107 is interposed therebetween.

In addition, in the second embodiment, the thickness of the polysilicon film 114a for forming gate electrodes in, for example, the p-FET region T2 is smaller than that of the polysilicon film 114 for forming gate electrodes in the n-FET region T1 in the process step shown in FIG. 11A. Accordingly, the volume ratio of the metal film 108 to the polysilicon film 114a is higher than that in the n-FET region T1. The same holds for the resistor regions R1 and R2 and the capacitor regions C1 and C2. As a result, if nickel is used for the metal film 108, NiSi is formed as FUSI structures in the n-FET region T1, the first resistor region R1 and the first capacitor region C1, whereas Ni₃Si is formed as FUSI structures in the p-FET region T2, the second resistor region R2 and the second capacitor region C2. That is, FUSI structures having different compositions are formed at a time.

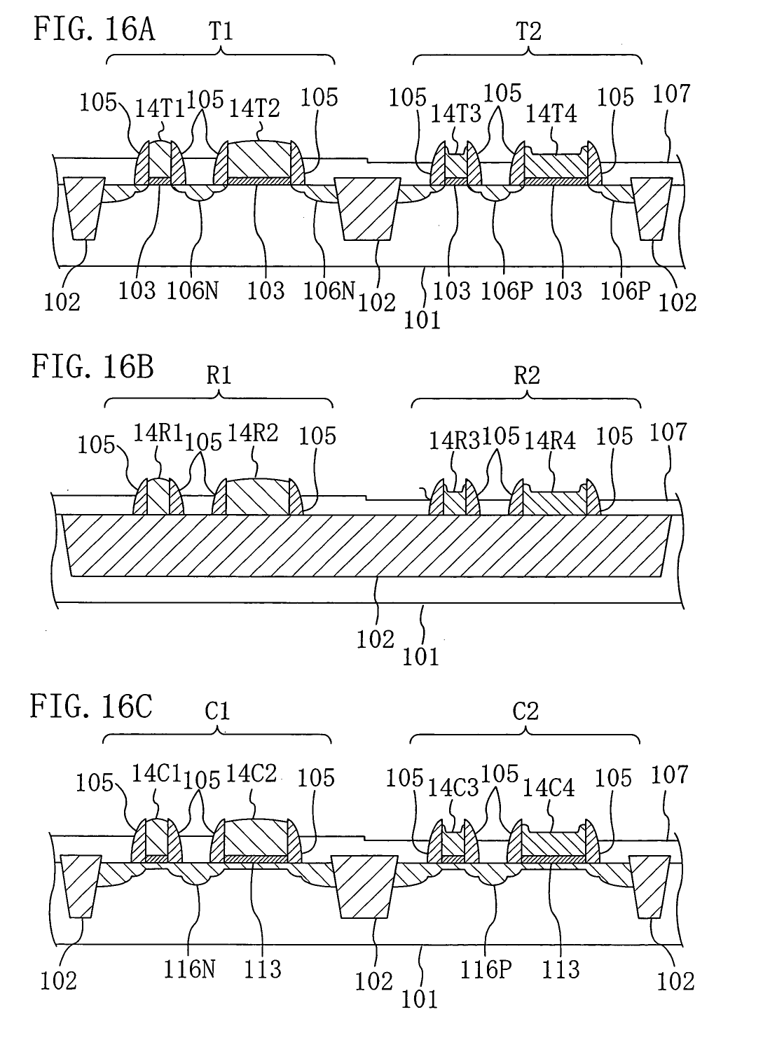

Then, as illustrated in FIGS. 16A through 16C, the unreacted metal film 108 remaining over the n-type source/drain regions 106N and the p-type source/drain regions 106P is removed by etching using a mixed solution in which hydrochloric acid and a hydrogen peroxide solution, for example, are mixed. Thereafter, an upper-level insulating film is deposited over the interlayer insulating film 107 including the FUSI gate electrodes 14T1 through 14T4, thereby forming contact holes and interconnections.

As described above, with the method for fabricating a semiconductor device of the second embodiment, a height difference is formed between the sidewall spacers 105 and each of the polysilicon films 114 and 114a for forming gates, so that trenches having a width corresponding to the width in, for example, the gate length are formed in a self-aligned manner during deposition of the metal film 108. Accordingly, a resist film, i.e., the second resist film 129 in this embodiment, according to planar dimensions of the gate electrodes, the resistors and the upper electrodes is formed on the metal film 108 in a self-aligned manner. As a result, the NiSi FUSI first and second gate electrodes 14T1 and 14T2, the NiSi FUSI first and second resistor elements 14R1 and 14R2 and the NiSi FUSI first and second upper electrodes 14C1 and 14C2 have the same composition, irrespective of the sizes (planar dimensions) thereof. In the same manner, the Ni₃Si FUSI third and fourth gate electrodes 14T3 and 14T4, the Ni₃Si FUSI third and fourth resistor elements 14R3 and 14R4 and the Ni₃Si FUSI third and fourth upper electrodes 14C3 and 14C4 have the same composition, irrespective of the sizes (planar dimensions) thereof. Moreover, n-FETs 111 and 121, the p-FETs 112 and 122, resistors 211, 221, 212 and 222 and capacitors 311, 321, 312 and 322 are formed at a time.

(Modified Example of Embodiment 2)

Hereinafter, a modified example of the second embodiment will be described with reference to the drawings.

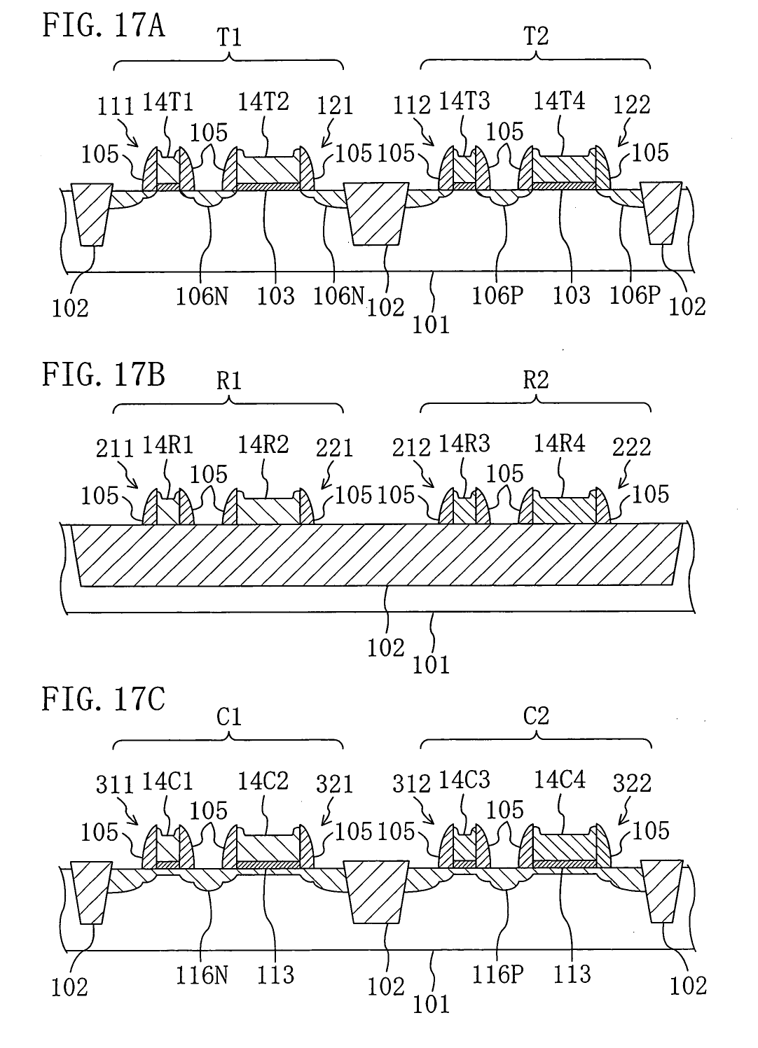

FIGS. 17A through 17C illustrate cross-sectional structures of a semiconductor device according to a modified example of the second embodiment. In FIGS. 17A through 17C, components also shown in FIGS. 8A through 8C are denoted by the same reference numerals, and description thereof will be omitted.

As illustrated in FIGS. 17A through 17C, in the semiconductor device of this modified example, trenches are formed in middle portions in the gate length direction (width direction) of upper portions of the first and second gate electrodes 14T1 and 14T2, the first and second resistor elements 14R1 and 14R2 and the first and second upper electrodes 14C1 and 14C2 in the n-FET region T1, the first resistor region R1 and the first capacitor region C1, respectively.

Now, only aspects of the method of this modified example different from those of the second embodiment will be described.

In a process step of etching portions of the metal film 108 located on the upper ends of the sidewall spacers 105 shown in FIGS. 14A through 14C, portions of the metal film 108 in the n-FET region T1, the first resistor region R1 and the first capacitor region C1 are not etched to the bottom of the second resist film 129 but are etched such that the metal film 108 remains on lower portions of the side faces of the second resist film 129. Specifically, when the second resist film 129 is removed, trenches are formed by bottom portions of the second resist film on the upper surface of the metal film on the polysilicon films 114 and 114a in cross section. It should be noted that portions of the metal film 108 on the upper ends of the sidewall spacers 105 should be removed. In this manner, in a subsequent silicidation step, trenches are formed in upper portions of the first and second gate electrodes 14T1 and 14T2, the first and second resistor elements 14R1 and 14R2 and the first and second upper electrodes 14C1 and 14C2.

As described above, a semiconductor device and a method for fabricating the device according to the present invention has the advantage of uniform FUSI structures. The present invention is especially useful for a semiconductor device including a field-effect transistor having a FUSI gate electrode and a method for fabricating the device.

What is claimed is:

1. A semiconductor device, comprising:
a first field-effect transistor including a first gate electrode; and
a second field-effect transistor including a second gate electrode,
wherein each of the first gate electrode and the second gate electrode is fully silicided with a metal and the first gate electrode and the second gate electrode have different gate lengths,
a trench is formed in an upper portion of the first gate electrode such that a rim portion of the first gate electrode is high and a middle portion of the first gate electrode in a gate length direction is low, and
the trench has a width depending on a gate length of the first gate electrode.

2. The semiconductor device of claim 1, wherein a trench is formed in an upper portion of the second gate electrode such that a rim portion of the second gate electrode is high and a middle portion of the second gate electrode in a gate length direction is low.

3. The semiconductor device of claim 1, wherein the first gate electrode has a gate length larger than that of the second gate electrode.

4. The semiconductor device of claim 1, wherein the first gate electrode and the second gate electrode have an identical metal content.

5. The semiconductor device of claim 1, wherein the first field-effect transistor and the second field-effect transistor are n-type field-effect transistors.

6. The semiconductor device of claim 1, wherein the first field-effect transistor and the second field-effect transistor are p-type field-effect transistors.

7. The semiconductor device of claim 6, further comprising:
a third field-effect transistor including a third gate electrode; and
a fourth field-effect transistor including a fourth gate electrode,
wherein the third field-effect transistor and the fourth field-effect transistor are n-type field-effect transistors,
each of the third gate electrode and the fourth gate electrode is fully silicided with a metal and the third gate electrode and the fourth gate electrode have different gate lengths, and
convex shapes are formed in upper portions of the respective third and fourth gate electrodes such that middle portions of the third and fourth gate electrodes in respective gate length directions are high.

8. The semiconductor device of claim 7, wherein the third gate electrode and the fourth gate electrode have an identical metal content.

9. The semiconductor device of claim 7, wherein each of the first gate electrode and the second gate electrode has a metal content higher than that of each of the third gate electrode and the fourth gate electrode.

10. The semiconductor device of claim 6, further comprising:
a third field-effect transistor including a third gate electrode; and
a fourth field-effect transistor including a fourth gate electrode,
wherein the third field-effect transistor and the fourth field-effect transistor are n-type field-effect transistors,
each of the third gate electrode and the fourth gate electrode is fully silicided with a metal and the third gate electrode and the fourth gate electrode have different gate lengths, and
trenches are formed in upper portions of the respective third and fourth gate electrodes such that rim portions of the third and fourth gate electrodes are high and middle portions of the third and fourth gate electrodes in respective gate length directions are low.

11. The semiconductor device of claim 10, wherein the third gate electrode and the fourth gate electrode have an identical metal content.

12. The semiconductor device of claim 10, wherein each of the first gate electrode and the second gate electrode has a metal content higher than that of each of the third gate electrode and the fourth gate electrode.

13. The semiconductor device of claim 1, further comprising a resistor fully silicided with the metal, a trench being formed in an upper portion of the resistor such that a rim portion of the resistor is high and a middle portion of the resistor in a width direction is low.

14. The semiconductor device of claim 1, further comprising a capacitor including an upper electrode fully silicided with the metal, a trench being formed in the upper electrode such that a rim portion of the upper electrode is high and a middle portion of the upper electrode in a width direction is low.

15. A method for fabricating a semiconductor device including a first field-effect transistor including a first gate electrode and a second field-effect transistor including a second gate electrode, the method comprising the steps of:
(a) forming first and second silicon gate electrodes made of silicon and having different gate lengths on a semiconductor region;
(b) forming insulating sidewall spacers on side faces of the first silicon gate electrode and the second silicon gate electrode;
(c) forming a height difference such that exposed upper surfaces of the first and second silicon gate electrodes are lower than upper ends of the sidewall spacers;
(d) forming a metal film on at least the sidewall spacers, the first silicon gate electrode and the second silicon gate electrode, after the step (c);
(e) selectively removing portions of the metal film on the upper ends of the sidewall spacers; and
(f) performing heat treatment on the metal film after the step (e), thereby forming a first gate electrode and a second gate electrode fully silicided with the metal film out of the first silicon gate electrode and the second silicon gate electrode.

16. The method of claim 15, wherein in the step (f), trenches are formed in upper portions of the respective first and second gate electrodes such that rim portions of the first and second gate electrodes are high and middle portions of the first and second gate electrodes in respective gate length directions are low.

17. The method of claim 15, wherein the step (a) includes the step of forming a first protective insulating film and a second protective insulating film on upper surfaces of the first silicon gate electrode and the second silicon gate electrode,
the sidewall spacers are also formed on side faces of the first protective insulating film and the second protective insulating film in the step (b), and
the first protective insulating film and the second protective insulating film are removed in the step (c), thereby forming the height difference.

18. The method of claim 17, wherein the step (c) includes the step of removing the first protective insulating film and the second protective insulating film, and then etching upper portions of the first silicon gate electrode and the second silicon gate electrode.

19. The method of claim 15, wherein the step (e) includes the steps of:
(e1) forming a protective film on the metal film and etching back the protective film, thereby exposing portions of the metal film on upper ends of the sidewall spacers from the protective film; and
(e2) etching the metal film using the protective film as a mask, thereby removing portions of the metal film on the upper ends of the sidewall spacers.

20. The method of claim 15, further comprising the step (g) of selectively forming an isolation region in an upper portion of the semiconductor region, before the step (a),
wherein the step (a) includes the step of forming a silicon resistor element made of silicon on the isolation region,
the step (b) includes the step of forming the sidewall spacers on side faces of the silicon resistor element,
the step (c) includes the step of forming a height difference such that an exposed upper surface of the silicon resistor element is lower than upper ends of the sidewall spacers,
the step (d) includes the step of forming the metal film on the silicon resistor element,
the step (e) includes the step of removing portions of the metal film on the upper ends of the sidewall spacers on the silicon resistor element, and
the step (f) includes the step of forming a resistor element of a resistor fully silicided with the metal film out of the silicon resistor element.

21. The method of claim 15, wherein the step (a) includes the step of forming, on the semiconductor region, a silicon upper electrode made of silicon,
the step (b) includes the step of forming the sidewall spacers on side faces of the silicon upper electrode,
the step (c) includes the step of forming a height difference such that an exposed surface of the silicon upper electrode is lower than upper ends of the sidewall spacers,
the step (d) includes the step of forming the metal film on the silicon upper electrode,
the step (e) includes the step of removing portions of the metal film on the upper ends of the sidewall spacers on the silicon upper electrode, and
the step (f) includes the step of forming an upper electrode of a capacitor fully silicided with the metal film out of the silicon upper electrode.
